(19) United States
(12) Patent Application Publication
(10) Pub. No.: US 2026/0160632 A1
(43) Pub. Date: Jun. 11, 2026

(54) LIQUID COOLING LEAK DETECTION SYSTEM

(71) Applicant: Nvidia Corporation, Santa Clara, CA (US)

(72) Inventors: Rouslan Lyubomirov Dimitrov, Newark, CA (US); John Franz, Tomball, TX (US); JeongYong Jeon, Pleasanton, CA (US)

(21) Appl. No.: 18/970,580

(22) Filed: Dec. 5, 2024

(51) Int. Cl. G01M 3/16; H05K 7/20

(52) U.S. Cl. CPC G01M 3/165; H05K 7/20781

(57) ABSTRACT

Systems and methods herein are for leak detection in a computing environment using a shaped leak sensor. The shaped leak sensor may include an insulating material, printed or applied thereon conductive traces on a first side, and an adhesive on a second side. The shaped leak sensor may be configured to be shaped to match at least a layout around a component in the computing environment. A detector can monitor an input from the shaped leak sensor to determine one or more of different states associated with the shaped leak sensor.

### TECHNICAL FIELD

At least one embodiment pertains to cooling in computer environments such as datacenters.

### BACKGROUND

Computer environments such as datacenters may be subject to liquid cooling. Liquid cooling may use cold plates to interface with computing features of a computer module. While liquid cooling enables improved heat removal from computing features, in support of improved computing performance, it may be subject to leaks. As such, leak detection may be performed using leak detection ropes, which can provide an alarm when a leak occurs as liquid from a leak contacts the leak detection rope. However, a leak detection rope may not be flexible and may not be seated flush or compliant with a surface that may accumulate or be subject to liquid from a leak. For instance, a leak detection rope or other such leak detection features may be difficult to manipulate around areas of a computing environment that may be subject to leaks from a liquid cooling loop, such as around critical processor and memory components. In addition, a leak detection rope or other such leak detection features (including flat rectangular designs) may have a limited surface area for leak detection and may have a limited bend radius. The limited bend radius may imply that such leak detection features may not be able to receive liquid at corners within a computer module. In view of all such deficiencies, the leak detection rope and other such leak detection features may not be cost effective. Other solid format sensors may have limitations relating to detection of a leak state within a liquid cooling loop.

### BRIEF DESCRIPTION OF DRAWINGS

FIG. 1 is an illustration of a datacenter subject to a shaped leak sensor, in at least one embodiment;

FIG. 2A is an illustration of computer module aspects of a shaped leak sensor, in at least one embodiment;

FIG. 2B is an illustration of an example computer module having areas for a shaped leak sensor, in at least one embodiment;

FIG. 2C is an illustration of interconnected shaped leak sensors provided within a computer module, in at least one embodiment;

FIG. 2D is an illustration of a layout aspects of shaped leak sensors in a computer module, in at least one embodiment;

FIG. 2E is an illustration of a manufacturing aspects of shaped leak sensors in a computer module, in at least one embodiment;

FIG. 3A is an illustration of shaping aspects to provide a shaped leak sensor, in at least one embodiment;

FIG. 3B is an illustration of circuit aspects of a detector associated with one or more shaped leak sensors, in at least one embodiment;

FIG. 3C is an illustration of states available using a detector associated with one or more shaped leak sensors, in at least one embodiment;

FIG. 3D is an illustration of a use of a shaped leak sensor in a compute or switch tray, in at least one embodiment;

FIG. 4 illustrates rack aspects in a system subject to a shaped leak sensor, according to at least one embodiment;

FIG. 5A illustrates a process flow for a system having a shaped leak sensor, in at least one embodiment;

FIG. 5B illustrates yet another process flow for a system having a shaped leak sensor, in at least one embodiment;

FIG. 6A illustrates an example datacenter, in which at least one embodiment from FIGS. 1-5B may be used;

FIG. 6B is a block diagram that schematically illustrates a computing system that may be a data center or a High-Performance Computing (HPC) cluster, in which at least one embodiment from FIGS. 1-5B may be used;

FIG. 6C illustrates an example computing environment, in which at least one embodiment from FIGS. 1-5B may be used; and

FIG. 6D illustrates a computer system, according to at least one example, in which at least one embodiment from FIGS. 1-5B may be used.

### DETAILED DESCRIPTION

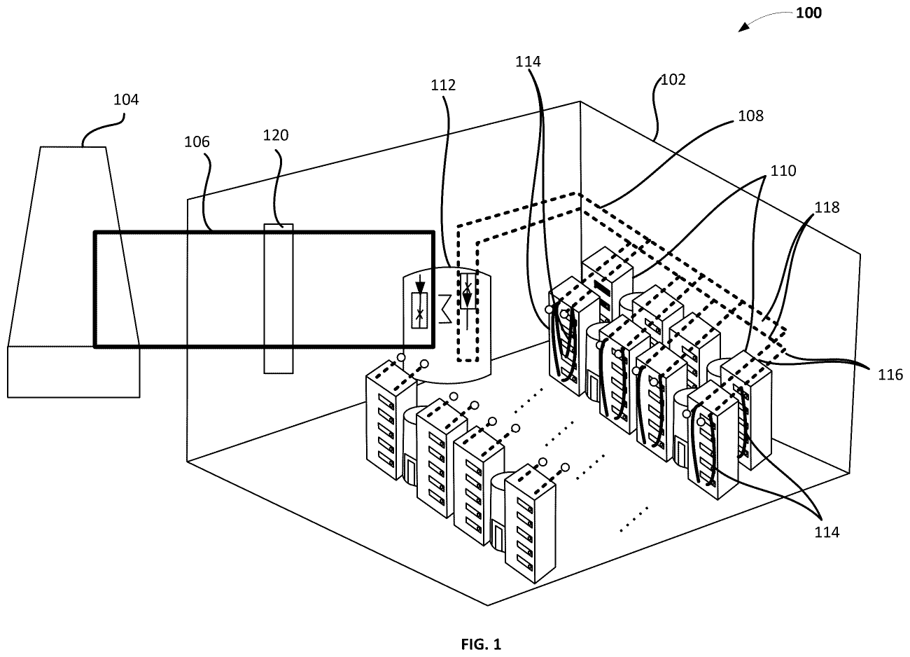

FIG. 1 is an illustration of a datacenter subject to a shaped leak sensor having a flexible insulating material, in at least one embodiment. To address limitations in liquid cooling in a datacenter, provided herein is a system and method of a shaped leak sensor that can match a geometry around components and features in the computer environment and that can be communicatively coupled together to extend leak detection capabilities. As used herein, a shaped leak sensor may be a reference to an insulating material comprising leak sensing features and comprising a shape or an ability to be shaped to conform with an application (such as the geometry around components and features in the computer environment). A shaped leak sensor may be provided from an insulating material, such as a flexible printed circuit board (or flex-PCB) having polyimide as a base material, and having printed or applied, on one side, a gold (or other conductive material such as one or more of gold, graphite, silver, or nickel) traces to perform leak detection. Further, the flex-PCB may be provided from polyamide, polyester, polyethylene naphthalate, or Polytetrafluoroethylene, as exemplary base materials. The flexibility of the sensors allows a traverse up/down and across gaps or surface level changes which may exist around components and features in the computer environment.

An adhesive may be provided on another side of the flex-PCB. The flex-PCB may also include a foam material at its perimeter to support pooling of any fluid from a leak in the computing environment. As such, the shaped leak sensors may be shaped by cutting (e.g. by scissors) or in any other suitable manner to be aligned together and can support plug-in capabilities using a prong and a socket connection between individual flex-PCBs without damaging the operation. The shaped leak sensors herein may include parallel traces to support being shaped by cutting of the flex-PCBs to form the shaped leak sensor. Further, the shaped leak sensor is able to be configured for individual applications in the computer environment by being calibrated to suit each individual application and, further, to distinguish between different states. This allows for very precise detection of specific ones of small liquid amounts in a leak for instance.

The states may include a missing/damaged shaped leak sensors in a daisy-chain of such shaped leak sensors that couple to different channels of an analog-to-digital converted (ADC) to allow voltage monitoring for leak detection, a shorted shaped leak sensor caused by metal components improperly contacting (from damage in the computer environment, in one example), and different voltage levels for different levels of leak that may occur. The ADC may be part of a detector, such as a baseboard management controller (BMC) or other application-specific integrated circuit (ASIC), to use reference values with input from the shaped leak sensors to determine a state associated with the shaped leak sensors. Therefore, instead of hardwired comparators, the ADC is able to use the reference values with the input in software or firmware of the ADC. Finally, the shaped leak sensors can support calibration to generate the reference values and support testing using a field-effect transistor (FET) to change resistance between the traces.

The shaped leak sensor herein can address leak detection may use of leak detection rope or other such leak detection features and from solid format sensors that may have state limitations and that may be difficult to manipulate around areas of a computing environment that may be subject to leaks, such as around critical processor and memory components. The flex-PCB-based shaped leak sensor can be shaped, conformed to uneven surfaces (over heat pipes and on top of cold plates), and adhered to and around areas of a computer environment that may be otherwise difficult to access and allow for monitoring of different states other than a leak in a liquid cooling system.

In one example, a computer module that may be a server tray or a switch tray or box can incorporate custom shaped flex-PCB sensors forming the shaped leak sensor. These shaped leak sensors may be placed, in a conformal manner, over a top surface of a cold plate, heat pipe, or trays and under or near all O-ring seals, hoses, manifolds, pipe junctions and fluid couplings, or around a rack in an effort to be as close as possible to all potential leak locations. All the shaped leak sensors used may include interlocking gold-plated traces with a predetermined spacing. In one example, the predetermined spacing may be 0.3 millimeters (mm). Further, when a conductive liquid that may be part of a liquid cooling loop contacts the shaped leak sensor, the traces and liquid may form a resistance, which may be detected by a detector that may be a sensing circuit. The shaped leak sensor may be terminated with 1.1 Mega Ohm (MΩ) resistor for presence detection. Further, in one example, there may be multiple (such as, two) 2.2 MΩ resistors being different shaped leak sensors that are in parallel as part of the termination for the shaped leak sensors. As such, when a resistance value is measured as having changed or that does not match a calibrated reference value, then it can be determined that one of the shaped leak sensors is disconnected or missing and, further, that a specific one of the shaped leak sensors is disconnected or missing.

FIG. 1 is a block diagram of an example datacenter 100 having a cooling system subject to improvements described in at least one embodiment. The datacenter 100 may be subject to a shaped leak sensor, in at least one embodiment. The datacenter 100 may be one or more rooms 102 having racks 110 and auxiliary equipment to house one or more servers on one or more server trays having circuit boards therein, which may be altogether referred to herein as computer modules. The datacenter 100 may be supported by a cooling tower 104 located external to the datacenter 100. The cooling tower 104 may dissipate heat from within the datacenter 100 by acting on a primary cooling loop 106. Further, a cooling distribution unit (CDU) 112 may be used between the primary cooling loop 106 and a secondary cooling loop 108 to enable extraction of the heat from the secondary cooling loop 108 to the primary cooling loop 106. The secondary cooling loop 108 can access various plumbing all the way into the server tray as required, in an aspect.

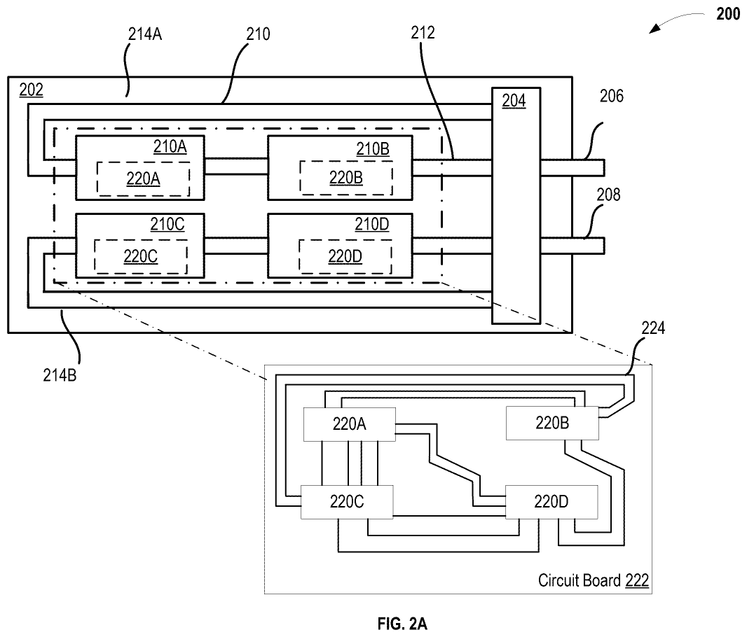

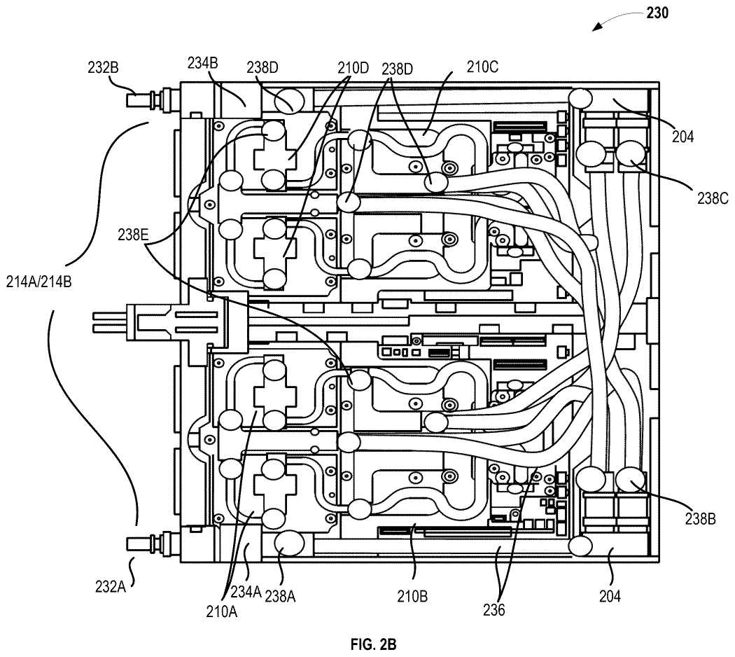

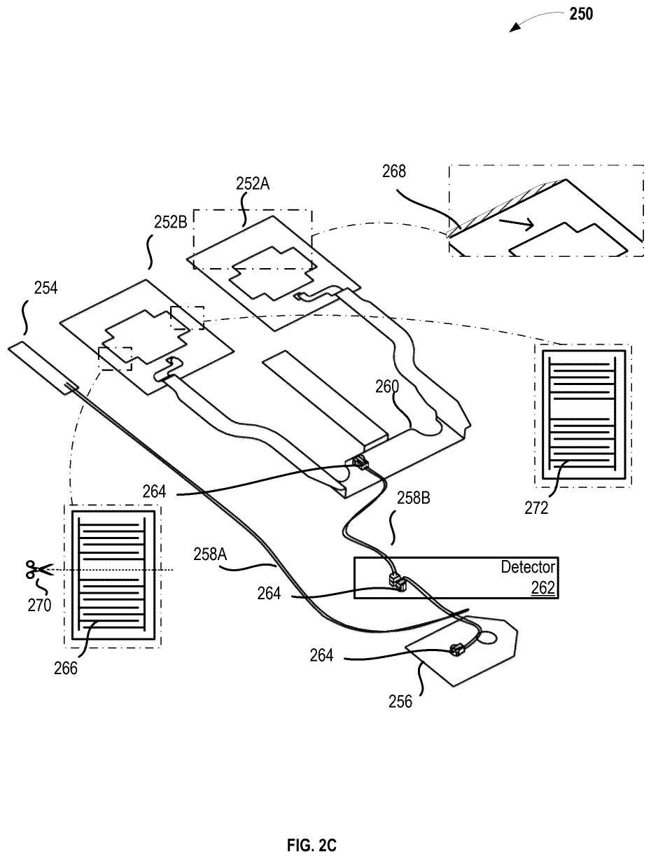

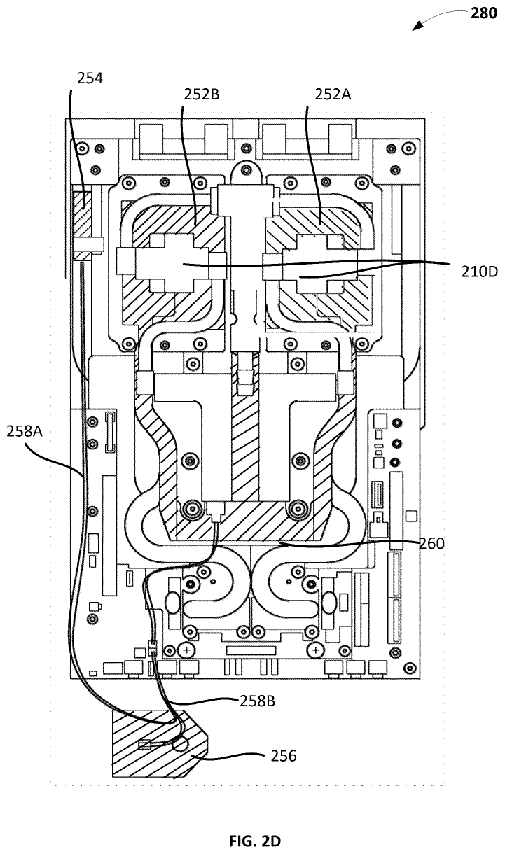

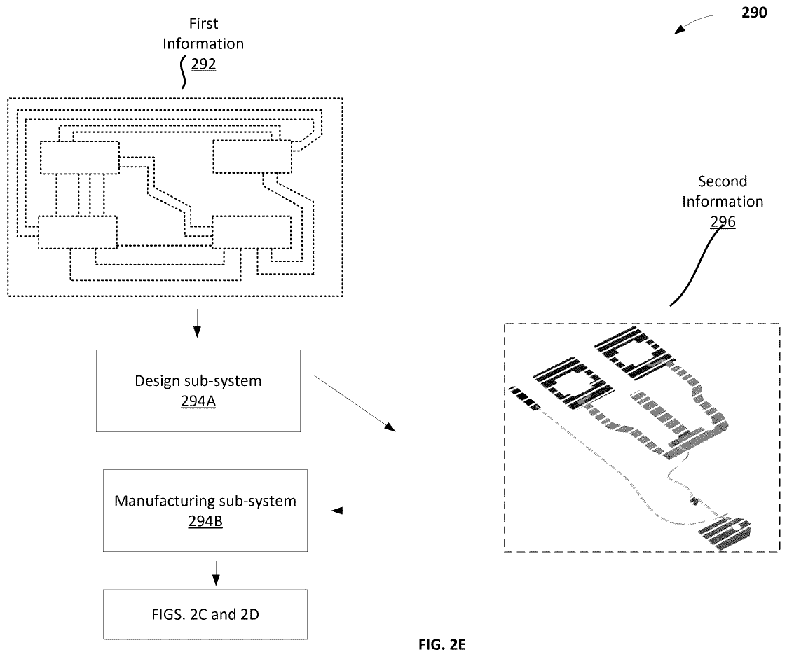

The primary and secondary cooling loops 106, 108 are illustrated as line drawings, but a person of ordinary skill would recognize that one or more plumbing features may be used. In an instance, flexible polyvinyl chloride (PVC) pipes may be used along with associated plumbing to move the media along in each of the primary and secondary cooling loops 106, 108. One or more pumps, in at least one embodiment, may be used to maintain pressure differences within the primary and secondary cooling loops 106, 108 to enable the movement of a media (such as, a primary media or a secondary media that may be a coolant or refrigerant) according to temperature sensors in various locations, including in the room, in one or more racks 110, and/or in server boxes or server trays within the racks 110. As used herein, at least the secondary cooling loop 108, which is associated with a primary cooling loop 106, may be configured to cool computing features of the computer module using a cold plate, and all such computing features and the secondary cooling loop may be subject to a shaped leak sensor, as detailed further in one or more of FIGS. 2A-6 herein.

In at least one embodiment, a secondary media in a secondary cooling loop 108 have an inlet temperate of above 0 degrees centigrade (° C.) but less than 40° C., and may exit with a temperature of about 60° C. In one example, a primary media in the primary cooling loop 106 may be used to cool the secondary media in the secondary cooling loop 108. The primary media and the secondary media may be at least water and an additive, for instance, glycol or propylene glycol. In operation, each of the primary and the secondary cooling loops 106, 108 have their own media. In an aspect, the media in the secondary cooling loops may be proprietary to requirements of the components in the server tray or racks 110.

The CDU 112 may be capable of sophisticated control of the primary and the secondary media, independently or concurrently, in the primary and the secondary cooling loops 106, 108. For instance, the CDU may be adapted to control the flow rate of a secondary media of the secondary cooling loop 108 so that the secondary media may be appropriately distributed to extract heat generated within the racks 110. Further, more flexible tubing 114 is provided from the secondary cooling loop 108, relative to the primary cooling loop, to allow entry to each computer module and to provide secondary media to the computing features therein. In the present disclosure, the computing features may be used interchangeably to refer to the heat-generating components that benefit from the present datacenter cooling system.

The tubing 118 illustrated in FIG. 1 and that may form part of the secondary cooling loop 108 may be referred to as room manifolds. Separately, additional tubing 116 extending from such tubing 118 may also be part of the secondary cooling loop 108 but may be referred to as row manifolds. Still further, the tubing 114 illustrated in FIG. 1 may enter the racks as part of the secondary cooling loop 108, but may be referred to as rack cooling manifold. Further, the row manifolds 116 may extend to all racks along a row in the datacenter 100. The plumbing of the secondary cooling loop 108, including the manifolds or tubings 118, 116, and 114 may be improved by at least one embodiment of the present disclosure. An optional chiller 120 may be provided in the primary cooling loop within datacenter 102 to support cooling before the cooling tower. To the extent additional loops exist in the primary control loop, a person of ordinary skill would recognize reading the present disclosure that the additional loops provide cooling external to the rack and external to the secondary cooling loop; and may be taken together with the primary cooling loop for this disclosure.

In at least one embodiment, in operation, heat generated within server trays of the racks 110 may be transferred from at least one cold plate to a media exiting the racks 110 via flexible tubing of the row manifold 114 of the second cooling loop 108. Pertinently, secondary media (in the secondary cooling loop 108) from the CDU 112, for cooling the racks 110, moves towards the racks 110. The secondary media from the CDU 112 passes from on one side of the room manifold having tubing 118, to one side of the rack 110 via row manifold 116, and through one side of the server tray via provided tubing 114. Spent secondary media (or exiting secondary media carrying the heat from the computing features) may exit out of another side of the server tray (such as, enters left side of the rack and exits right side of the rack for the server tray after looping through the server tray or through components on the server tray). The spent secondary media that exits the server tray or the rack 110 comes out of different side (such as exiting side) of tubing 114 and moves to a parallel, but also exiting side of the row manifold 116. From the row manifold 116, the spent secondary media may move in a parallel portion of the room manifold 118 going in the opposite direction than the incoming secondary media (which may also be the renewed secondary media), and towards the CDU 112. Further, the spent secondary media may have an exit temperature of above 0° C. and may specifically be in the range of 40-60° C.

In at least one embodiment, the spent secondary media may exchange its heat with a primary media in the primary cooling loop 106 via the CDU 112. The spent secondary media may be renewed (such as relatively cooled when compared to the temperature at the spent second coolant stage) and ready to be cycled back to through the second cooling loop 108 to the computing features or components. Various flow and temperature control features in the CDU 112 enable control of the heat exchanged from the spent secondary media or the flow of the secondary media in and out of the CDU 112. CDU 112 is also able to control a flow of the primary media in primary cooling loop 106.

FIG. 2A is an illustration of computer module aspects of a shaped leak sensor, in at least one embodiment. The aspects 200 may include server-level features and may include a computer module 202 having at least one server manifold 204 to allow entry and egress of a cooling media of a secondary cooling loop 108, from a rack 110. However, the server manifold 204 may include separate channels for inlet and for exit of media of the secondary cooling loop 108, which is illustrated as an extension from the rack to be secondary cooling loops 214A, 214B, within the computer module.

The secondary media may enter from a rack manifold, via inlet pipe 206 and may exit via outlet pipe 208. The secondary media, on the server side may travel via inlet line 210, through one or more cold plates 210A, 210B, and via outlet line 212 to the manifold 204. This represents at least one or multiple secondary cooling loops 214A, 214B within the server tray or box 202. These multiple secondary cooling loops 214A, 214B may be an extension of the secondary cooling loop 108 interfacing with the primary cooling loop 106 as they provide the same or substantially the same secondary media from the secondary cooling loop 108 to the cold plates 210A-210D. In at least one embodiment, the cold plates 210A-210D are associated with at least one computing component or feature 220A-220D. In addition, while illustrated as different cold plates, the illustrated cold plates 210A-210D may be part of a large single cold plate structure have integrated contact points that are specifically over the underlying computing features 220A-220D. A computing feature 220A-220D may include processors, memories, and switches or regulators. In one example, the processors may include graphics processing units (GPUs), central processing units (CPUs), data processing units (DPUs), quantum processing units (QPUs), a plurality of parallel processing units (PPUs) and ASICs.

In at least one embodiment, even though illustrated as having one inlet and one outlet or exit for inlet line 210 and for outlet line 212, there may be multiple intermediate lines, such as flexible pipes associating the cold plate with the respective inlet line 210 and outlet line 212. In at least one embodiment, the intermediate lines directly couple the cold plate to the manifold 204 are provided inlet and outlets for such connections. In at least one embodiment, media adapters are provided to enable such coupling. In at least one embodiment, the media adapters are sized to the inlet and outlet provisions in the cold plate and the manifold 204.

FIG. 2A also illustrates that computer module aspects 200 may include a circuit board 222 having interconnect features 224 on a first side (top side, as illustrated) and on a second side (bottom side, similar features as the top side illustrated or soldered features relative to the top side). The interconnect features 224 may couple one or more of the computing features 220A-220D together. The interconnect features 224 may include copper traces, plated and non-plated through-holes, solder points, transmission lines, and electrically-insulating circuit board material over which such copper traces and solder points may lie.

In at least one implementation, a secondary cooling loop 108; 214A; 214B may be used to capture a largest portion of heat generated within the system, while targeting the computing features 220A-220D. For instance, it is possible to capture ambient heat that may be other than the targeted computing features 220A-220D. Therefore, it is possible to capture about 80-90% of heat generated from a computer module or a rack by one or more of the secondary cooling loops 108; 214A; 214B. This is even though the secondary cooling loop 108; 214A; 214B may operate at temperatures that are greater than 0° C. and even though the secondary cooling loop 108; 214A; 214B may operate using a water-based media. FIG. 2A generally illustrates that the computer module 202, having the secondary cooling loop 214A; 214B may include O-ring seals, hoses, manifolds and fluid couplings. All such aspects of the secondary cooling loop 214A; 214B may benefit from the shaped leak sensors herein, in an effort to be as close as possible to all potential leak locations.

FIG. 2B is an illustration of an example computer module 230 having areas for a shaped leak sensor, in at least one embodiment. FIG. 2B illustrates a dual tray, relative to a single tray configuration of FIG. 2D, for instance. The example computer module 230 may be one or more of the computer module 202 in FIG. 2A. The computer module 230 may include a server tray, compute tray, or server box having multiple ones of the shaped leak sensors that are placed under the different aspects of the secondary cooling loop 214A; 214B. The shaped leak sensors may be associated with circuitry of a detector to detect leaks and to notify a cluster management through a baseboard management controller (BMC) of a datacenter. The detector may be voltage-based leak detector or a capacitance-based leak detector, in at least one example. There may be high-risk leak points within a computer module 230 and while quality and manufacturing processes may include pressure testing on completed cooling loop assemblies to verify construction standards, fluid connections of all types may still be at risk for a leak. A computer module 230 may have 20 or more locations of potential leaks and some that are around critical processor and memory components, and have tight bend radii.

In FIG. 2B, at least one secondary cooling loop 214A or 214B is illustrated with an inlet side 232A and an outlet, exit, or egress side 232B. Each of the inlet side 232A and the exit side 232B may be associated with at least one adapter 234A; 234B that may be coupled to pipes, tubes, or lines 236. The inlet side 232A brings in a relatively cooler media to cool one or more computing features underlying one or more cold plates 210A-210D. The media may be distributed from the inlet side 232A and may be returned via an exit side 232B. The distribution and the return may be provided via at least one manifold 204 that may be separate for the distribution and for the return side, as illustrated in FIG. 2B.

FIG. 2B particularly illustrates that there may be multiple locations, some generally marked 238A-238E, that may be identified as potential leak areas. For instance, the coupling of pipes, tubes or lines 236 to an adapter 234A; 234B may be identified as a potential leak area 238A, 238D. The adapter 234A; 234B may be a quick disconnect (QD) type of an adapter. The areas associated with the at least one manifold 204 may be also identified as a potential leak areas 238B, 238C. Further, areas associated with the computing features, such as a GPU, a CPU, a DPU, a QPU, or a PPU and having the overlying cold plates 210A-210B may be also identified as potential leak areas 238E. All such areas may require shaped leak sensors to reduce risk of a leak that may occur but also to reduce a time period of the leak that may occur. In one example, the areas 238A, 238B of the couplings may experience mate/un-mate connection cycles during service events and may be subject to potential leaks that may occur at a time and that may continue to occur after a service event. All such areas may have a tight bend radii and parts thereof that may not contact a leak detector rope.

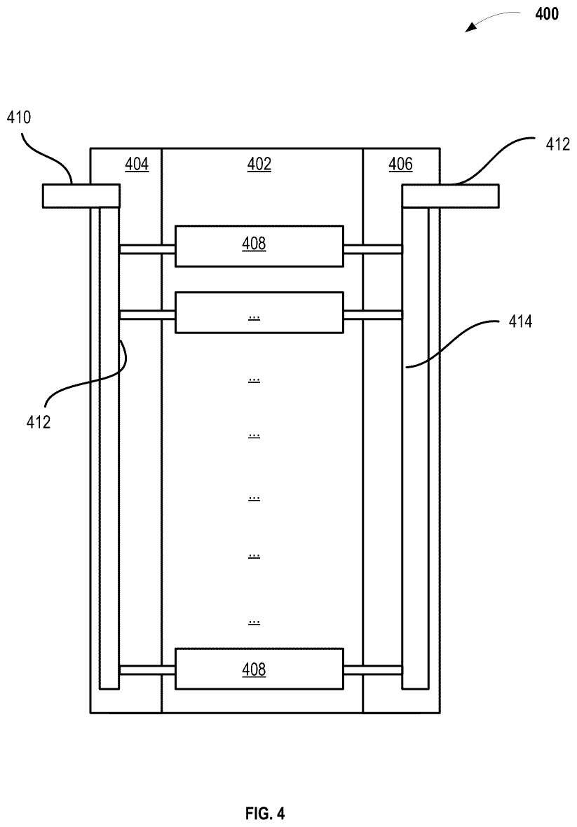

While a leak pan may be provided in a manner that is above a bottom power shelf of a rack and that may funnel leaked liquid through a drain hose to prevent such leaked liquid from entering a high-voltage section of a rack, there are benefits from recognizing a leak as soon as it occurs or recognizing a state associated with an area of a liquid cooling system to determine an appropriate response. Liquid in contact with a power shelf or other power infrastructure can present personnel hazards. Therefore, a shaped leak sensor may be used with such collection points having a leak bucket under a rack, for instance, that can collect liquid from a drain tube and from vertical manifolds of a rack. While the illustration in FIG. 2B may be to a computer module 202, 230, there are applications of the shaped leak sensor herein that may apply to a rack, such as described with respect to at least FIG. 4 herein. In one example, a leak bucket may have a spot leak sensor therein that may be associated with the shaped leak sensor of the computer module as part of a daisy chain, which may be altogether coupled to a rack infrastructure manager (RIM) or the BMS.

FIG. 2C is an illustration of interconnected shaped leak sensors 250 that may be associated together and provided within a computer module, in at least one embodiment. The interconnected shaped leak sensors 250 may include two or more of a CPU/DPU/QPU/PPU shaped leak sensor 260, one or more GPU shaped leak sensors 252A, 252B, an adapter shaped leak sensor 254, and a manifold shaped leak sensor 256. The interconnected shaped leak sensors 250 may be have passive shaped leak sensors that may be inserted with the example computer module 230 in FIG. 2B. Such an implementation is detailed with respect to at least FIG. 2D herein. FIG. 2C also illustrates that each of the shaped leak sensors 252A-260 may include multiple conducive traces 266 to enable cutting 270, as part of a shaping capability, for the shaped leak sensors 252A-260.

As illustrated, the conductive traces 266 may extend as interlacing fingers from one conductor on one side and another conductor on another side. The gap between the interlacing fingers allows for shorting between the conductors to change a resistance or a capacitance of the shaped leak sensors. Further, the cutting 270 of a first side of a ring-shaped leak sensor 252A; 252B, maintains the integrity of the shaped leak sensor as a second side of the ring remains intact 272 and allows for leak detection through the second side instead of the first side. For instance, if a liquid drop or other media causes contact between the interlacing fingers of conductors of the conductive traces 266. This allows each shaped leak sensor to be intricately provided in tight radii and other areas around components without disturbing the components, in one example.

In at least one example, the interconnected shaped leak sensors 250 may be interconnected by wires or cables 258A, 258B that may be straight or Y-type cables. The wires or cables 258A, 258B may be mated to a detector 262, such as a voltage (V)-based detector or a capacitance-based detector. In at least one embodiment, the detector 262 may be capable of supporting any suitable communication protocol to communicate with the ADC, including BACnet®, Internet Protocol (IP), and N2® communication protocols. The ADC, in turn, may use I2C® or USB® to communicate with the BMC, and the BMC may use Ethernet to communicate with a cluster management system (CMS). As illustrated, one or more of the shaped leak sensors are shaped to suit its application, to be compliant to a surface in its application, and to be within corners at a tight bend radius.

Further, at least the adapter shaped leak sensor 254 of the interconnected shaped leak sensors 250 may be provided for a small leak collection tray under the adapters capable of fluid couplings within a computer module 202; 230. However, in one example, the adapter shaped leak sensors 254 may not attach directly to the detector 262 or to a cold plate. Instead, a Y-cable 258A may be provided to enable coupling of the adapter shaped leak sensor 254 to a manifold shaped leak sensor 256, which then couples to a detector 262. In at least one example, such an indirect coupling of a shaped leak sensor 256 to the detector 262 may be partly based on daisy chaining between one shaped leak sensor to another shaped leak sensor.

In addition, each of the shaped leak sensor of the interconnected shaped leak sensors 250 may be shaped to match and to be mounted to their respective structures or surfaces based in part on an adhesive layer provided on at least one side to support peel-and-stick usage. Each shaped leak sensor may also include a foam material 268 at its perimeter to support pooling (indicated by the arrows for movement of media collected hereon) of any fluid from a leak in the computing environment. The matched respective structures or surfaces may represent layouts within a computer module 202; 230. Therefore, a system for leak detection, such as the interconnected shaped leak sensors 250 in FIG. 2C, in a computing environment may include at least one shaped leak sensor of the interconnected shaped leak sensors 250. The at least one shaped leak sensor has a flexible insulating material, printed or applied thereon multiple conductive traces on a first side, and an adhesive on a second side. The shaped leak sensor may be configured to be shaped to match at least a layout around a component, such as the computing features, adapters, manifolds, tubes, and the like, in the computing environment.

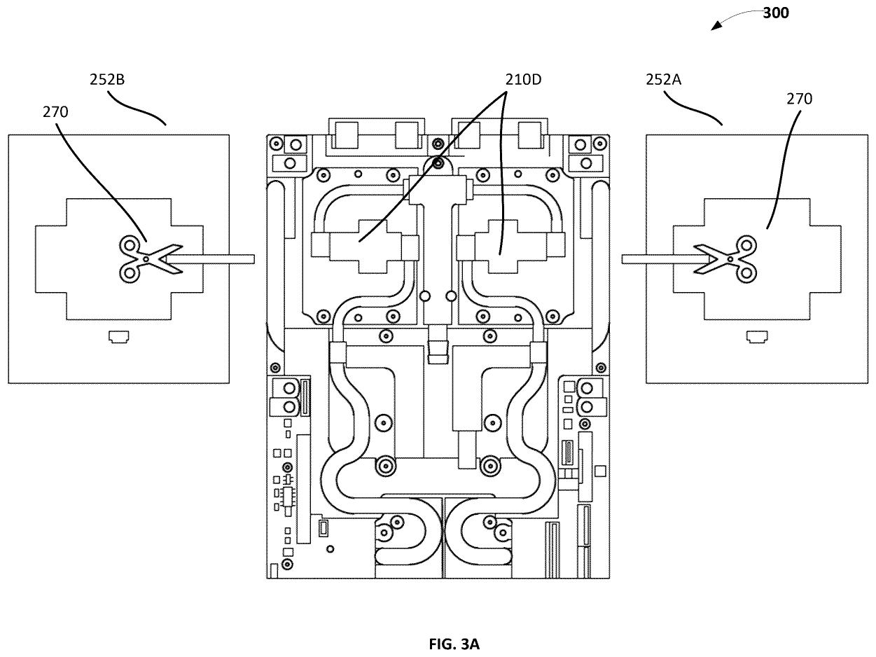

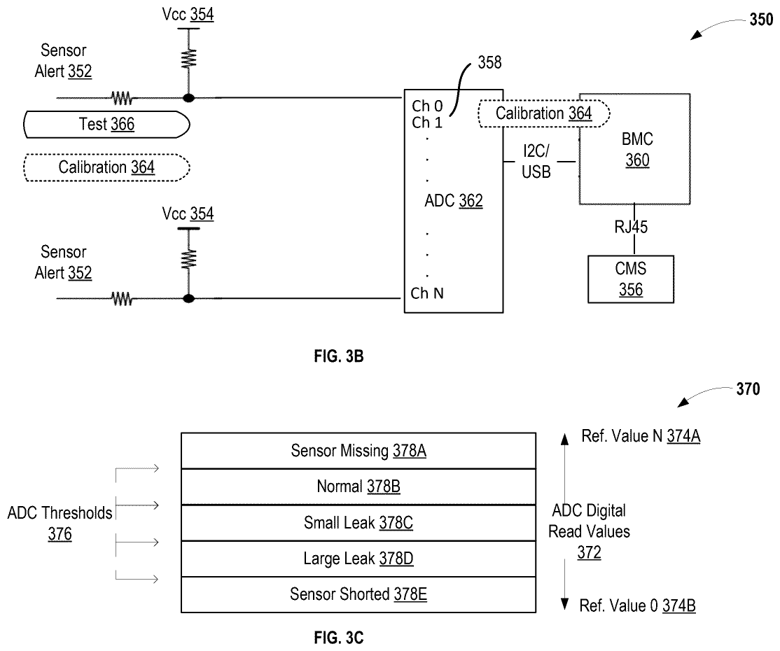

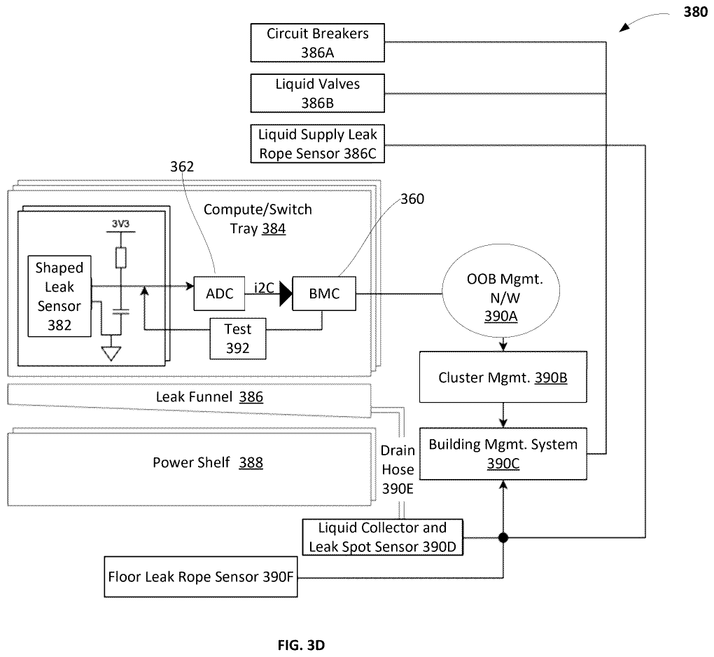

The detector 262 being a voltage-based or a capacitance-based leak detector can monitor an input from the shaped leak sensor to determine one or more of different states associated with the shaped leak sensor, as detailed further with respect to at least FIGS. 3B, 3C herein. The insulating material for a shaped leak sensor may be flexible insulating material and may include one or more of polyimide, polyamide, polyester, polyethylene naphthalate, or Polytetrafluoroethylene. The conductive traces may include one or more of gold, graphite, silver, or nickel, as at least one component of such materials used therein.

In at least one embodiment, the shaped leak sensors may be daisy chain or, otherwise, linked together through a suited connector or connectors that may be compatible with each other. In one instance, the CPU shaped leak sensor 260 and one or more GPU shaped leak sensors 252A, 252B may be associated together using a lockable flip zero insertion force (ZIF) style connector or a Molex® connector 264. The connectors 264 herein may all represent one or more of a prong or a socket to allow for the shaped leak sensors to be associated together or one another by a plug-in arrangement and to be associated with the detector 262 either directly or through a connected shaped leak sensor. A prong or a socket, as used herein, may be electrically and/or communicatively conductive elements of a power or communication connection that enable transmission of power or communication between one prong or socket once connected to another prong or socket.

The CPU shaped leak sensor 260 and one or more GPU shaped leak sensors 252A, 252B may use a 2-pin header with removable and reversable cable in communication with the detector 262. The adapter shaped leak sensor 254 and the manifold shaped leak sensor 256 may share a Y-cable 258A that connects to the detector 262. Further, at least the connector 264 may determine an alignment of the ring-shaped leak sensor 252A; 252B. While a cut 270 may be used to align a ring-shaped leak sensor to a left-side or a right-side component, as described further with respect to FIG. 3A, the ring-shaped leak sensor is also aligned so that cabling does not need to extend around components or interfere with components. This can be done by ensuring that the connector 264 is in line with other connectors of other ring-shaped leak sensors or is closest to other connectors of other shaped leak sensor that are generally in the same area.

In addition, the adapter shaped leak sensor 254 and a manifold shaped leak sensor 256 may be associated together to the Y-cable 258A using a soldered connection. This may be due to low-profile of spaces available with a tray's fluid hose that may be residing directly above the area of potential leak to be addressed. Further, other than the soldered connection, other ends of the Y-cable 258A may use a same connector as the CPU shaped leak sensor 260 and one or more GPU shaped leak sensors 252A, 252B. FIG. 2C also illustrates that the CPU shaped leak sensor 260 is uniquely shaped to extend through tubes, adapters, or manifolds associated with the CPU cold plate 210C to reach to the GPU cold plates 210D. In at least one embodiment, the CPU shaped leak sensor 260 may be in the shape of a letter E and may be provided to connect with a motherboard, which is associated with the detector 262, using a 2-pin cable 258B and using the Molex connector.

Further, the GPU shaped leak sensors 252A, 252B may be shaped in the form of rings and may connect to a central shaped leak sensors, such as the CPU shaped leak sensor 260. The CPU shaped leak sensor 260 and the GPU shaped leak sensors 252A, 252B may be electrically in parallel. Therefore, presence of the intended shaped leak sensor may be determined by evaluation of resistances associated with the system for leak detection, as detailed with respect to one or more of FIG. 3B or 3C herein. For instance, one or more of the shaped leak sensors and associated cables may be terminated by a 2.2 MΩ presence resistor and when all sensors are properly connected, a final parallel resistance will be exposed to the motherboard.

FIG. 2D is an illustration of a layout aspects 280 of shaped leak sensors in a computer module, in at least one embodiment. As illustrated, the shaped leak sensors may be set forth to be compliant and around tight corner radii of computing features, adapters, manifolds, and the like. Therefore, it is possible to use the shaped leak sensors 252A-260 to address one or more potential leak areas 238A-238E. Further, the potential leak areas 238A-238E may be determined from provided layout information of a circuit board 222 and a secondary cooling loop 214A; 214B. Therefore, the shaped leak sensors 252A-260 may be designed to be installed during the construction of one or more cold plates 210A-210D. While illustrated as distinct cold plates 210A-210D, a large single format cold plate having integrated smaller cold plates 210A-210D may be provided to cover one or more of the computing features 220A-220D illustrated in the figures herein.

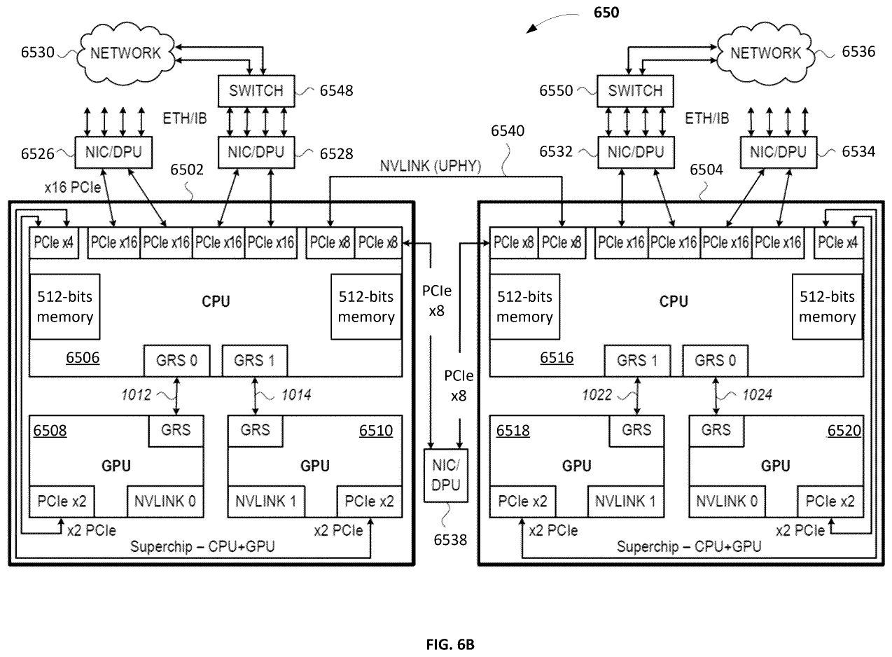

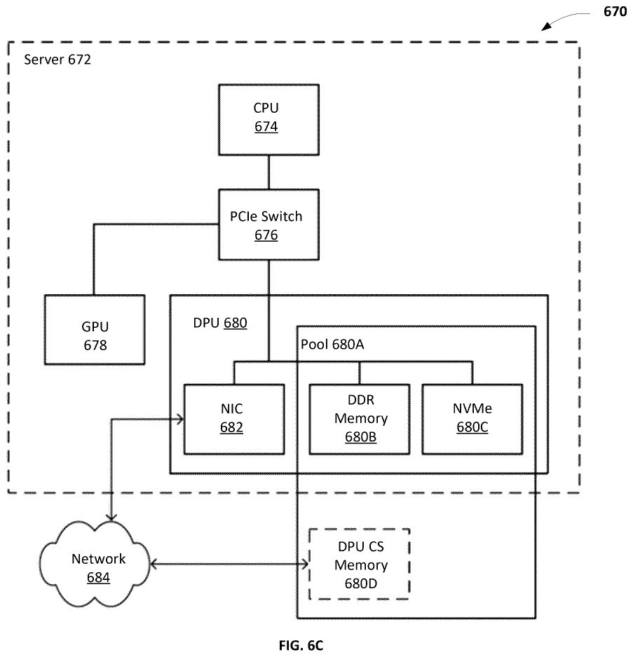

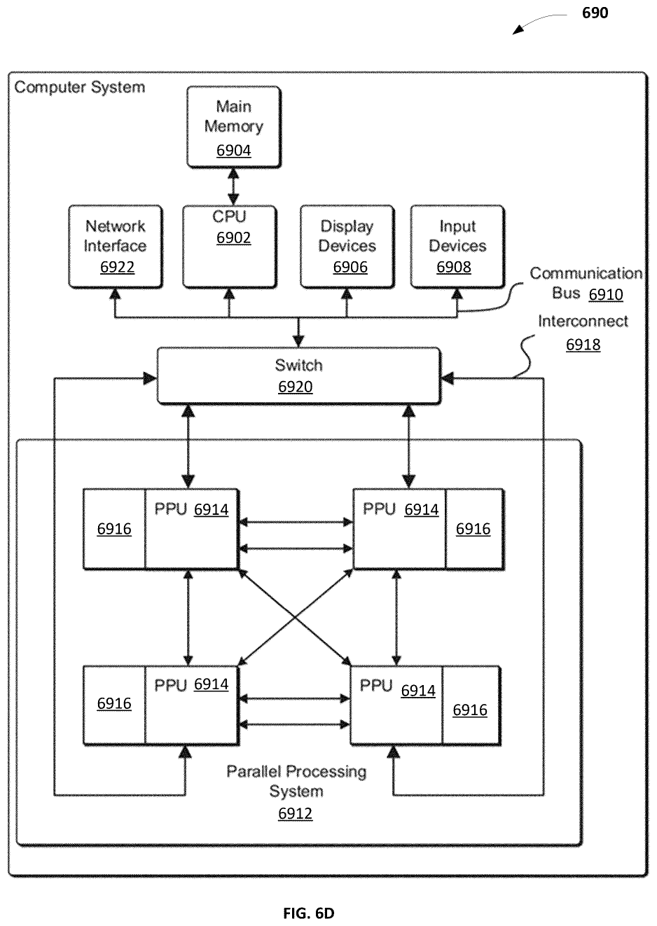

In at least one embodiment, a computer system incorporating computing features descried with respect to FIG. 6A may be used with first information associated with one or more of a first layout of a circuit board 222 or a second layout of a secondary cooling loop 214A; 214D to generate second information associated with the design of the shaped leak sensors 252A-260 and their interconnection. As such, the shaped leak sensors 252A-260 herein can be shaped o optimize a surface area to be covered that may be in addition to the specific potential leak areas 238A-238E described herein. Further, the interconnection of the shaped leak sensors 252A-260 provides an opportunity for the shaped leak sensors 252A-260 to be checked for damage and can support optimal assurance that leak detection herein will function from the earliest stages of assembly to full tray integration. In one example, the shaped leak sensors 252A-260 may be a single continuous shape that can fit around copper structures and that can be installed below metal fittings and pipes of a cold plate.

FIG. 2E is an illustration of manufacturing aspects 290 for a shaped leak sensor, in at least one embodiment. Particularly, FIG. 2E illustrates that, for a circuit board and a provided layout thereof, in the first information 292, it is possible to design a shaped leak sensor or interconnected shape leak sensors (broken lines), as part of second information 294 provided from a design sub-system 294A. The design may be provided to a manufacturing sub-system 294B to enable shaping of the shaped leak sensor or interconnected shape leak sensors illustrated in at least FIGS. 2C and 2D herein. The design sub-system 294A and the manufacturing sub-system 294A may be part of a system of one or more circuits that may include at least a processor and a memory having instructions to be executed by the processor to perform functions of design and manufacturing. For instance, the design sub-system 294A can receive the first information 292 and the manufacturing sub-system 294B may use the second information 296 to prepare the shaped leak sensor or interconnected shape leak sensors for the layout of the circuit board 222. Therefore, one or more of aspects 290 of the system having the design sub-system 266 and the manufacturing sub-system 268 may be performed using some features or all features of a datacenter 600 in FIG. 6A.

Although illustrated in FIG. 2E, the second information 296 may be in the form of specifications or code to be used to print, machine, or stamp-out features of at least the shaped leak sensor or interconnected shape leak sensors described herein. For instance, the specifications or code may be used with a three-dimensional (3D) printer, a Computer Numerical Control (CNC) machine, or other such manufacturing feature of a manufacturing sub-system 294B to prepare one or more shaped leak sensor or interconnected shape leak sensors.

FIG. 3A is an illustration of shaping aspects 300 to provide a shaped leak sensor, in at least one embodiment. For instance, after an initial design, when a need arises to replace any one shaped leak sensor of the shaped leak sensors 252A-260 illustrated and that may be a continuous shape, it is possible to cut 270; 302 at least one side of a ring-shaped leak sensor 252A; 252B to allow for a part of the ring-shaped leak sensor 252A; 252B to spread apart and to fit around a cold plate 210D. As the other side of the ring-shaped leak sensor 252A; 252B remains intact 272, the integrity of the ring-shaped leak sensor 252A; 252B remains as intended and capable of detecting a leak or other states once fitted around a component without need to disturb the component. Therefore, when replacing a ring-shaped leak sensor 252A; 252B for a left-side GPU 220C, it may be required to cut 270 one specific side of the ring-shaped leak sensor to allow for a fit around the left-side GPU 220C illustrated and, for a right-side GPU 220A, it may be required to cut an opposite side of the ring-shaped leak sensor to allow for a fit around the right-side GPU 220A. However, the ring-shaped leak sensor 252A; 252B can be provided without any specific bias as to a side of installation, as each of the shaped leak sensors 252A-260 may include multiple conductive traces 266 all throughout the ring of the ring-shaped leak sensor 252A; 252B. Further, the conductive traces 266 in each sensor may be an array of gold-plated conductive traces.

While the shaped leak sensors herein may function without cutting, other than the initial shaping to suit the design of the secondary cooling loop, a cut to one side of at least a ring-shaped leak sensor can be supported while maintaining integrity of the system for leak detection because of the continuity through the other side of the ring-shaped leak sensor herein. Therefore, it is possible to provide a singular ring-shaped leak sensor that can be used with left or ride side component features of a computer module. Further, if the cutting 302 interferes with both left and right sides on a same ring-shaped leak sensor, a missing or disconnected alert may be indicated. As the system herein is also able to detect different states associated with the shaped leak sensors, it is possible to address such issues instantly. The multiple conductive traces 266, therefore, may include at least one pair of parallel conductive traces which may be configured to be shaped to provide the shaped leak sensor. The parallel conductive traces may be configured to provide redundancy in sensing a leak upon at least one conductive trace of the at least one pair of parallel conductive traces being shaped by the cut 302 performed, in one example.

FIG. 3B is an illustration of circuit aspects 350 of a voltage-based leak detector associated with one or more shaped leak sensors, in at least one embodiment. The circuit aspects 350 illustrate that each of the one or more shaped leak sensors may be enabled to provide a sensor alert 352 to a respective channel 358 of an ADC 362. There may be one or more of biasing resistances and power supplies for a respective shaped leak sensor. The ADC 362 may be provided with a supply voltage Vcc 354 as well. However, there may be reference or threshold values 376 (in FIG. 3C) that may be between a larger range of reference values 374A-374N. Such reference or threshold values 374A-374B, 376 may be retained, in software or firmware, by the ADC 362, during a calibration for one or more of the shaped-leak sensors. One or more of the reference or threshold values 374A-374B, 376 may be applied to received values from the sensor alerts 352 in each of the channels 358; and can be used to determine a specific state 378A-378E that may be associated with each of the one or more shaped leak sensors providing the sensor alerts 352. The ADC 362 may provide information about the state of one or more of the shaped leak sensors to the BMC 360. Therefore, hardware in the circuit aspects 350 of FIG. 3B can set alert thresholds in the one or more shaped leak sensors using the ADC 362 or the BMC 260.

In one example, when a resistance of a shaped leak sensor exceeds an allowable range in one of the reference or threshold values 374A-374B, 376, an interrupt signal may be set and may be provided to a detector 262 associated with the BMC 360. In one example, the detector may be in reference to one or more of an ADC 362 and a BMC 360. The ADC 362 may be able to aggregate all interrupts received and can notify the BMC 360. The BMC 360 can access the ADC 362 through an Inter-Integrated Circuit (I2C®) or USB® Protocol. However, it is possible for the BMC 360 to directly receive input from each of the shaped leak sensors. The BMC 360 can also determine when a read has failed, which may be indicative of a shaped leak sensor having failed.

Further, as resistance associated with a shaped leak sensor increases, a digital value (or digital read value) associated therewith may be at a higher range of the reference or threshold values 374A-374B. The ADC 362 or the BMC 360 can determine that a relevant shaped leak sensor may be disconnected or a missing 378A state. This may be reported as a fault within the BMC 360 or from the ADC 362 to the BMC 360. When a resistance associated with a shaped leak sensor decreases, a digital value associated therewith may be at a middle or lower range of the reference or threshold values 374A-374B. The ADC 362 or the BMC 360 can determine that a leak has occurred in an area or with a feature associated with the shaped leak sensor. The leak may be a small leak 378C state or a large leak 378D state. When a resistance associated with a shaped leak sensor is zero or close to zero, a digital value may be a lowest in the reference or threshold values 374A-374B. The ADC 362 or BMC 360 can determine that the shaped leak sensor is in a shorted state 378E. In one example, when metal fragments or a component of a computer module 202 may be dislodged, it may contact a shaped leak sensor and may cause the shorted 378E state for the shaped leak sensor. The ADC 362 or the BMC 360 may determine that an associated shaped leak sensor is in a fault condition. Otherwise, the ADC 362 or the BMC 360 may determine a normal 378B state for the shaped leak sensors providing voltage associated with digital values that are within the normal ADC thresholds 376.

In at least one embodiment, a visible indication (such as, a color or strobe via a light emitting diode (LED)) may be provided for display on a computer module having the leak, but can also be provided to the BMC 360 or to a CMS 356 using a connector. The connector may be an RJ-45 (or Ethernet) connector between at least the BMC 360 and the CMS 356. All connectors associated with a system for leak detection may be dedicated to leak detection alone and can enable leak detector indications at a front of a tray or a computer module 202 or to one or more of remote devices. Therefore, while the shaped leak sensors and associated integrated circuitry (IC) may be on a mainboard or circuit board 222, leak detector indications may be support for determination of a leak or a state of the shaped leak sensors without having to access the circuit board 222.

Further, it is possible to calibrate and test a system for leak detection based in part on a type of media used in a secondary cooling loop. For instance, where PG25® is used as a cooling media in a secondary cooling loop and is monitored for leak detection, it is possible to calibrate and test the system for leak detection beforehand using PG25. For instance, it may be determined that one drop of PG 25 may cause a reading decrease of 2% within a ADC 362. The reading decrease may be with respect to a resistance that may be configured within the system for leak detection having the specific shaped leak sensor. However, it may be possible that the 2% decrease may be indicative of a component tolerance of a shaped leak sensor. Therefore, to make the system for leak detection resilient against false triggers, a threshold used therein for detecting a drop can be increased from 2% to 5%. In at least one embodiment, a threshold indicative of a change in a state associated with a shaped leak sensors may be between 5% and 16%. Pertinently, this threshold may be indicative of a range of a small leak to a large leak for PG25. Similarly, for deionized (DI) water as a media, the range may be from 10% and 39% to indicate a small leak to a large leak. Further, it is possible to program a type of liquid during installation or at runtime for the shaped leak sensors, where the BMC may store and implement references or thresholds relating to states for the shaped leak sensor that are associated with the type of liquid programmed thereto.

In at least one embodiment, to compensate for component variability, upon first boot, the system for leak detection herein can assume a dry version or state of a computing environment, as part of a calibration for the system, and can perform actual dry measurement using the dry state for one or more shaped leak sensors herein. A dry version or state of a computing environment, as used herein, may be in reference to a condition in the computing environment where no liquid is present, where the liquid may be provided as part of a test, calibration, or a leak within the computing environment. When it is determined that the dry measurements are within reasonable bounds (such as, using an absolute range of 0.51-0.53), then the system may construct thresholds or reference values that may be based at least in part on the reasonable bounds.

As such, the shaped leak sensors herein may be configured for calibration or testing for one of different applications in the computing environment. Further, at least such calibration can be performed in a dry version of the computing environment to determine reference values for more than just the dry state. One or more calibration module(s) 364 may be used to perform the calibration. At least one aspect of the one or more calibration module(s) 364 is to provide a dry state for the calibration on the side of the shaped leak sensors. At least another aspect of the one or more calibration module(s) 364 is to provide the references or threshold for the ADC or the BMC to use with respect to the digital read values obtained in real time from the shaped leak sensors. For instance, it is possible to incorporate leaks, failures, and other different states to provide calibration to the different states available in each shaped leak sensor. The detector 262 that may be one or more of the ADC 362 or the BMC 360 may be configured to distinguish between the different states 370 based at least in part on different voltages (including changes—such as increases or decreases) provided in the input from the circuit aspects 350, with respect to the references or thresholds that may be calibrated in the system for leak detection herein.

Further, the system for leak detection herein incorporates resetting of the reference values or thresholds. This may be required in situations where the shaped leak sensors are replaced during service or when a type of the media used is changed. In at least one embodiment, the BMC 360 may be used to program thresholds or reference values for each of the shaped leak sensors. Then, when a resistance of a shaped leak sensor exceeds an allowable range that may be with reference to the thresholds or reference values, the BMC 360 can be interrupted from performing any routine operation. The BMC 360 can query the interrupting shaped leak sensor through the I²C interface to receive further state information or other information with which to determine a state associated with the shaped leak sensor.

FIG. 3C is an illustration of states 370 available using a voltage-based leak detector associated with one or more shaped leak sensors, in at least one embodiment. The states 370 may be provided in reference to one or more references or thresholds 376 associated with the ADC digital read values 372 that may be digital values 374A-374B from an ADC 362 based in part on voltage values from a shaped leak sensor. The references or thresholds 376 may reflect upper and lower digital values 374A-374B illustrated with respect to the different states 378A-378E and, therefore, it is appreciated that there may be references or thresholds 376 corresponding to a sensor missing 378A state, a small leak 378C state, a large leak 378D state, and a sensor shorted 378E state.

For a dual tray, there may be multiple sets of interconnected shaped leak sensors. As such, each set of interconnected shaped leak sensor may have or use its own ADC channel, with the arrangement requiring at least two ADC channels. Further, the dual tray configuration may result in four sensor groups. For instance, there may be a left and a right manifolds and a left and a right cold plate, as in FIG. 2B, and therefore, there may be four distinct shaped leak sensors. Then, when a resistance change occurs that is outside of a nominal value, the interconnected shaped leak sensors may interrupt the BMC 360. The BMC 360 can read the all of the available ADC values (which may be four ADC values from the four shaped leak sensors). The BMC 360 can match the ADC digital read values 372 with predefined or predetermined ranges based in part on a calibration 364 for the four different shaped leak sensors. As a result of the matching, the BMC 360 will be able to determine a state 370 of a specific one of the shaped leak sensors, including if it is in a sensor disconnected state, a normal state, a small leak state, a large leak state, or sensor shorted state. The BMC 360 can trigger an event notification containing the fault condition of the associated state of a specific one of the shaped leak sensors for the group of interconnected shaped leak sensors.

In at least one embodiment, the BMC 360 is able to be interrupted by the ADC or any of the shaped leak sensors. For instance, to avoid polling the ADC, from the BMC, a sense integrated circuit (IC) may be used to raise an interrupt when references or thresholds 376 that may be predefined or predetermined are exceeded. The ADC 362 can support a continuous monitoring mode with windowing thresholds that includes an upper bound and lower bound for the references or thresholds 376. The ADC can be used to assert an alert if one of the ADC digital read values 372 on one of an ADC channel 358 is outside of a windowed threshold that reflects an ADC threshold 380, in one example.

An FPGA may perform as the ADC 362 and can receive sensor alerts 352 through a serial general-purposes input/output (SGPIO) and can route it to the BMC 360 to indicate that one or more of the ADC channels 358 have asserted an alert. The BMC 360 may, separately, monitor the SGPIO. In one example, a LEAK DETECT ALERT (low or high) may be asserted on the SGPIO. On interrupt assertion, the BMC 360 can query all the ADC channels to determine which ADC channel faulted. The BMC 360 can then start polling the ADC to monitor if the leak develops and to notify an event listener regarding any updates.

The system for leak detection herein is able to perform testing that pertains to leak self-testing. For instance, a leak detection and response can be tested via an IO expander. A test module 366 may be used and may include a field effect transistor (FET) or other electrical component that can vary resistance, voltage, or capacitance in the system for leak detection and that can be removably coupled to one or more of the shaped leak sensor to simulate the different states for the shaped leak sensor. For instance, the output of an IO may be set to high via the test module 366 and will pull a sensor input to low to simulate a leak, for testing purposes. In at least one embodiment, all service events may generate an event log or register an event log locally or remotely. At least the remote event log may occur using a universal resource identifier (URI) location for the remote event log. The event log may include a standard error message identifier (ID) and may include message parameters to indicate one or more of the shaped leak sensors that may be associated with the event. In at least one embodiment, a back-up shutdown timer configuration may be provided to allow configuration to a timeout value. Then, upon a timer expiration and after a large leak has been detected, the BMC 360 may be caused to shut down a computer module 202; 230.

FIG. 3D is an illustration of a use 380 of a shaped leak sensor in a compute or switch tray, in at least one embodiment. Each compute or switch tray 384 may include a shaped leak sensor 382. The shaped leak sensor 382 may be available for other components associated with the compute or switch tray 384, including the circuit breakers 386A, the liquid valves 386B, the leak funnel 386, a drain hose 390E, and the power shelf 388. The shaped leak sensor 382 may work with other leak sensors, including a liquid supply leak rope sensor 386C, a floor leak rope sensor 390F, and a liquid collector and leak spot sensor 390D. The use 380 may include a cluster shutdown protocol. For instance, once a leak is detected from any of the sensors 382, 386C, 390D, 390F, a rack shutdown may be performed. When a small leak is detected, such as only by a single compute or switch tray 384, a deployment of the cluster shutdown protocol may cause a next checkpoint to be performed. When a leak is detected by certain sensors, such as a floor leak rope sensor 390F or by a shaped leak sensor 382 of multiple compute or switch trays 384, a more substantial response than a next checkpoint may be performed. A more substantial response may be required at least in part due to possibility of electric shock hazard in any aspect of use 380 illustrated.

A system in the use 380 illustrated may need to trigger an immediate shutdown as part of the cluster shutdown protocol and as part of the more substantial response. In one example, power at a rack-level may be cut off using circuit breakers 386A. One or more liquid valves 386B may be shut off. A cluster management software 390B may aggregate leak signals from individual nodes representing the compute or switch tray 384 in the racks. In one example, the cluster management software 390B may present one or more configuration options for an aggregate leak signal to send an alarm and do nothing else; to send an alarm, trigger software shutdown followed by power isolation and liquid valve shut off; and to send an alarm, trigger immediate power isolation and liquid valve shut off.

The configuration options may be specified for different classes of severity. For instance, a small leak from a single node may cause a next checkpoint in the configuration options to be performed. A large leak from a single node or any leak type from multiple nodes may cause the more substantial response to be performed. A sensor fault may cause a different response altogether to address the sensor. A BMS 360 may be used to control the circuit breakers 386A and liquid valves 386B. The cluster management 390B and the BMS 360 may establish a communication path, using an out of band management network 390A (OOB Comm. N/W) to perform one or more of the aforementioned aspects.

FIG. 4 illustrates rack aspects in a system subject to a shaped leak sensor, according to at least one embodiment. A rack 402 has brackets 404, 406, to enable hanging of one or more cooling loop components within the rack 402. In at least one embodiment, rack manifolds 412, 414 may be provided to guide media from row manifolds to the computer modules 408 with the rack 402. The rack manifolds 412 may pass media of a secondary cooling loop from the row manifolds through conduit 410, through the server trays or boxes 408, out of the egress row manifold 414, and back into the row manifold via the egress conduit 412. The shaped leak sensor herein may be used in any of the illustrated server tray or box forming the computer modules 408 and may also benefit from additional local distribution units if there is a need to increase pressure of media flow at any level of a rack. Therefore, although described with respect to a computer module, the system for leak detection may be applied to a rack to provide leak detection within by compliant surfaces within tight radii of the rack. In such an implementation and in at least one example, the leak detection may be monitored from within a computer module on the rack that may have the BMC and the ADC parts of the circuit aspect 350 from FIG. 3B.

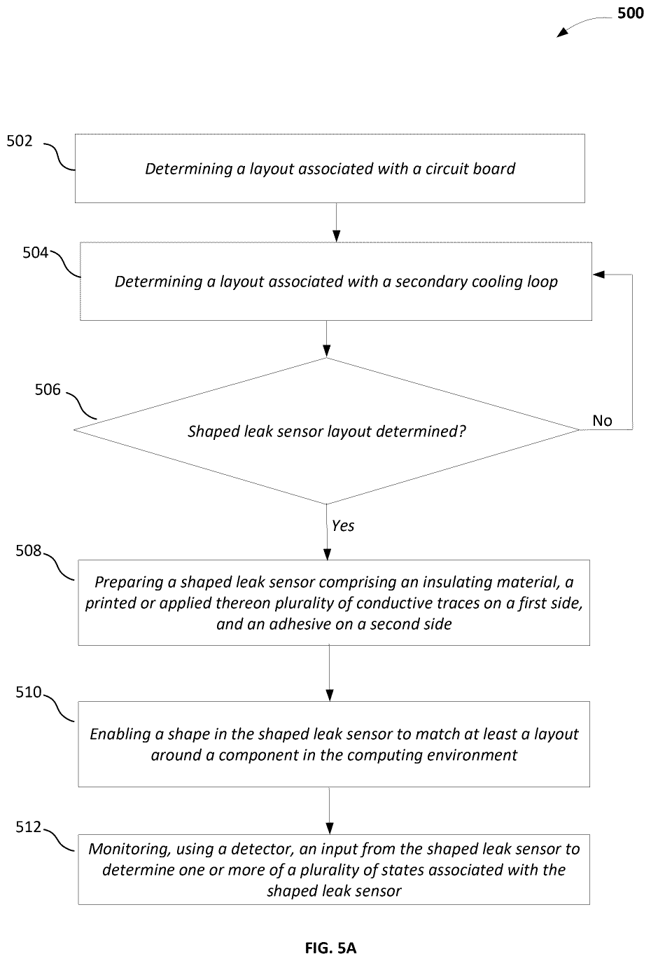

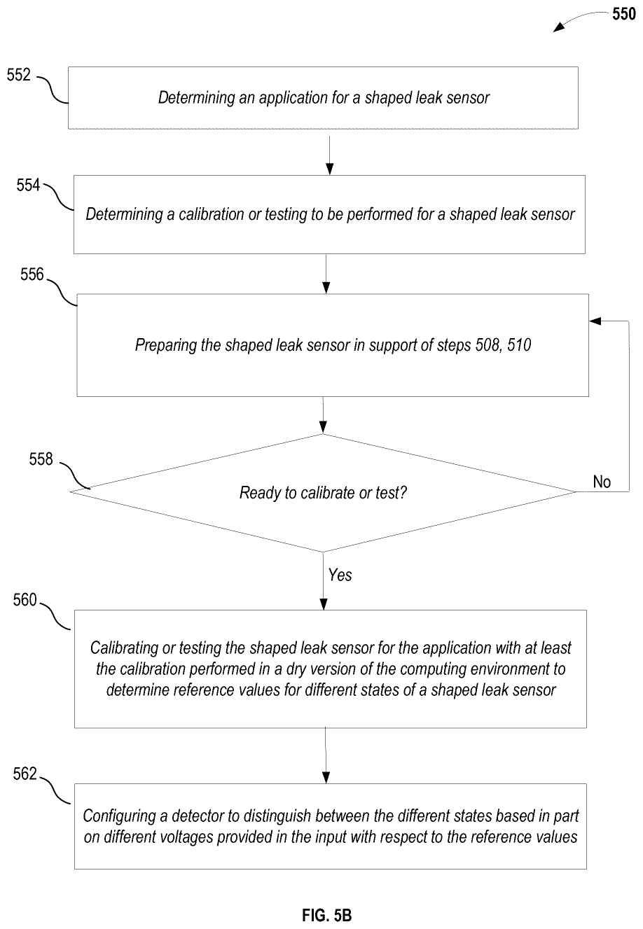

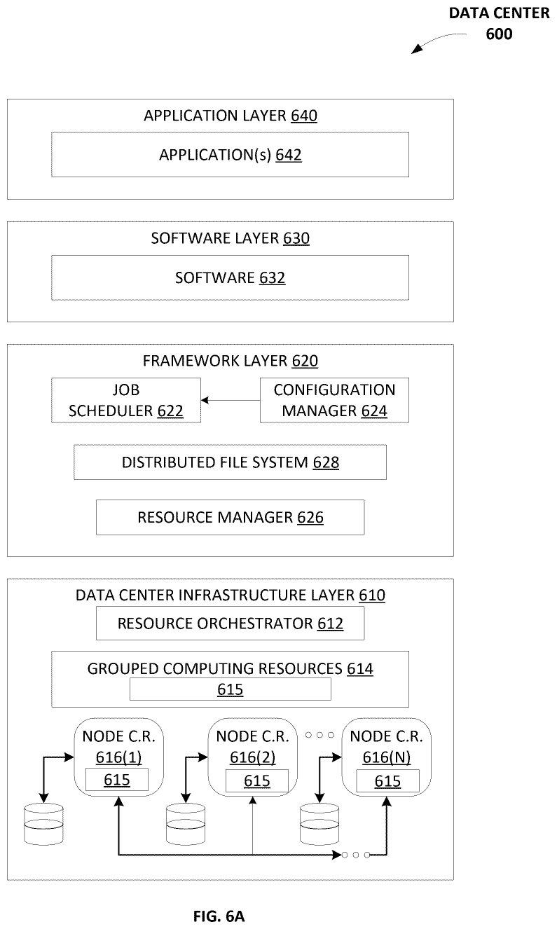

FIG. 5A illustrates a process flow or method for a system having shaped leak sensor, in at least one embodiment. The method 500 may include determining 502 a layout associated with a circuit board. The layout may be as described with respect to FIG. 2E. The method 500 may include determining 504 a layout associated with a secondary cooling loop. This may be a layout of colds plates, adapters, tubes, and manifolds of the secondary cooling loop. The method 500 may include verifying or determining 506 that a shaped leak sensor layout has been determined from a least the layout associated with the secondary cooling loop. The method 500 may include preparing 508 a shaped leak sensor comprising an insulating material, a printed or applied thereon plurality of conductive traces on a first side, and an adhesive on a second side. The method 500 may include enabling 510 a shape in the shaped leak sensor to match at least a layout around a component in the computing environment. For example, the shape of a CPU shaped leak sensor may be shaped according to the layout of one or more of colds plates, adapters, tubes, and manifolds of the secondary cooling loop associated with a CPU. The method 500 may include monitoring 512, using a detector, an input from the shaped leak sensor to determine one or more of different states associated with the shaped leak sensor. The detector may be a voltage-based leak detector.

The method 500 may include a further step or sub-step, where the insulating material is a flexible insulating material that includes one or more of polyimide, polyamide, polyester, polyethylene naphthalate, or Polytetrafluoroethylene. Further, in the method 500, the conductive traces may include one or more of gold, graphite, silver, or nickel. The method 500 may include a further step or sub-step of enabling a foam or volumetric material at a perimeter of the shaped leak sensor to support pooling of fluid from a leak in the computing environment.

The method 500 may include a further step or sub-step of allowing the shaped leak sensor to be associated with a further shaped leak sensor by a plug-in arrangement using one or more of a prong or a socket. The method 500 may include a further step or sub-step of associating with the detector either directly or through the further shaped leak sensor. The method 500 may include a further step or sub-step of enabling at least one pair of parallel conductive traces in the plurality of conductive traces. The at least one pair of parallel conductive traces may be configured to be shaped to provide the shaped leak sensor and to provide redundancy in sensing a leak upon at least one conductive trace of the at least one pair of parallel conductive traces being shaped.

FIG. 5B illustrates yet another process flow or method 550 for a system having a shaped leak sensor, in at least one embodiment. The method 550 of FIG. 5B may be used alone or in combination with the method 500 of FIG. 5A by detailing further steps or sub-steps for the method 500 in FIG. 5A. The method 550 may include determining 552 an application for a shaped leak sensor. The method 550 may include determining 554 a calibration or testing to be performed for a shaped leak sensor. The determination of the calibration or testing to be performed may be based in part on the application. The method 550 may include preparing 556 the shaped leak sensor in support of steps 508, 510 of the method 500 in FIG. 5A. The method 550 may include verifying or determining 558 that shaped leak sensor is ready to calibrate or test. The method 550 may include calibrating or testing 560 the shaped leak sensor for the application with at least the calibration performed in a dry version of the computing environment to determine reference values for different states of a shaped leak sensor. The method 550 may include configuring 562 a detector to distinguish between the different states associated with a leak detection sensor and may be based in part on different voltages provided in the input with respect to the reference values.

FIG. 6A illustrates an example datacenter 600, in which at least one embodiment from FIGS. 2A-5B may be used. For instance, the example datacenter 600 may be used to support one or more of the preparing or enabling steps to be used to generate or provide a shaped leak sensor for at least one underlying component of the example datacenter 600. However, the datacenter 600 may also include computer modules subject to a shaped leak sensor, in at least one embodiment, as described with respect to FIGS. 1-5B herein.

In at least one embodiment, datacenter 600 includes a datacenter infrastructure layer 610, a framework layer 620, a software layer 630, and an application layer 640. In at least one embodiment, such as described in respect to FIGS. 1-5B, features of the shaped leak sensor may be performed inside or in collaboration with the example datacenter 600. Also, features to generate or provide a shaped leak sensor for at least one feature of a computer module or rack may be performed inside or in collaboration with the example datacenter 600. In at least one embodiment, the infrastructure layer 610, the framework layer 620, the software layer 630, and the application layer 640 may be partly or fully provided via computing components on server trays located in racks 110 of the datacenter 100. This enables cooling systems of the present disclosure to direct cooling to certain ones of the computing features in an efficient and effective manner. Further, aspects of the datacenter, including the datacenter infrastructure layer 610, the framework layer 620, the software layer 630, and the application layer 640 may be used to support selection or design for a shaped leak sensor as herein discussed with at least reference to FIGS. 1-5B above. As such, the discussion in reference to FIG. 6A may be understood to apply to the hardware and software features required to enable or support provision of a shaped leak sensor, for instance.

In at least one embodiment, as in FIG. 6A, datacenter infrastructure layer 610 may include a resource orchestrator 612, grouped computing resources 614, and node computing resources (“node C.R.s”) 616(1)-616(N), where “N” represents any whole, positive integer. In at least one embodiment, node C.R. s 616(1)-616(N) may include, but are not limited to, any number of central processing units (“CPUs”) or other processors (including accelerators, field programmable gate arrays (FPGAs), graphics processors, etc.), memory devices (such as dynamic read-only memory), storage devices (such as solid state or disk drives), network input/output (“NW I/O”) devices, network switches, virtual machines (“VMs”), power modules, and cooling modules, etc. In at least one embodiment, one or more node C.R.s from among node C.R. s 616(1)-616(N) may be a server having one or more of above-mentioned computing resources.

In at least one embodiment, grouped computing resources 614 may include separate groupings of node C.R.s housed within one or more racks (not shown), or many racks housed in datacenters at various geographical locations (also not shown). Separate groupings of node C.R.s within grouped computing resources 614 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 612 may configure or otherwise control one or more node C.R.s 616(1)-616(N) and/or grouped computing resources 614. In at least one embodiment, resource orchestrator 612 may include a software design infrastructure (“SDI”) management entity for datacenter 600. In at least one embodiment, resource orchestrator may include hardware, software or some combination thereof.

In at least one embodiment, as shown in FIG. 6A, framework layer 620 includes a job scheduler 622, a configuration manager 624, a resource manager 626 and a distributed file system 628. In at least one embodiment, framework layer 620 may include a framework to support software 632 of software layer 630 and/or one or more application(s) 642 of application layer 640. In at least one embodiment, software 632 or application(s) 642 may respectively include web-based service software or applications, such as those provided by Amazon Web Services, Google Cloud and Microsoft Azure. In at least one embodiment, framework layer 620 may be, but is not limited to, a type of free and open-source software web application framework such as Apache Spark™(hereinafter “Spark”) that may utilize distributed file system 628 for large-scale data processing (such as “big data”). In at least one embodiment, job scheduler 622 may include a Spark driver to facilitate scheduling of workloads supported by various layers of datacenter 600. In at least one embodiment, configuration manager 624 may be capable of configuring different layers such as software layer 630 and framework layer 620 including Spark and distributed file system 628 for supporting large-scale data processing. In at least one embodiment, resource manager 626 may be capable of managing clustered or grouped computing resources mapped to or allocated for support of distributed file system 628 and job scheduler 622. In at least one embodiment, clustered or grouped computing resources may include grouped computing resource 614 at datacenter infrastructure layer 610. In at least one embodiment, resource manager 626 may coordinate with resource orchestrator 612 to manage these mapped or allocated computing resources.

In at least one embodiment, software 632 included in software layer 630 may include software used by at least portions of node C.R.s 616(1)-616(N), grouped computing resources 614, and/or distributed file system 628 of framework layer 620. One or more types of software may include, but are not limited to, Internet web page search software, e-mail virus scan software, database software, and streaming video content software.

In at least one embodiment, application(s) 642 included in application layer 640 may include one or more types of applications used by at least portions of node C.R.s 616(1)-616(N), grouped computing resources 614, and/or distributed file system 628 of framework layer 620. One or more types of applications may include, but are not limited to, any number of a genomics application, a cognitive compute, and a machine learning application, including training or inferencing software, machine learning framework software (such as PyTorch, TensorFlow, Caffe, etc.) or other machine learning applications used in conjunction with one or more embodiments.

In at least one embodiment, any of configuration manager 624, resource manager 626, and resource orchestrator 612 may implement any number and type of self-modifying actions based on any amount and type of data acquired in any technically feasible fashion. In at least one embodiment, self-modifying actions may relieve a datacenter operator of datacenter 600 from making possibly bad configuration decisions and possibly avoiding underutilized and/or poor performing portions of a datacenter.

In at least one embodiment, datacenter 600 may include tools, services, software or other resources to train one or more machine learning models or predict or infer information using one or more machine learning models according to one or more embodiments described herein. In at least one embodiment, in at least one embodiment, a machine learning model may be trained by calculating weight parameters according to a neural network architecture using software and computing resources described above with respect to datacenter 600. In at least one embodiment, trained machine learning models corresponding to one or more neural networks may be used to infer or predict information using resources described above with respect to datacenter 600 by using weight parameters calculated through one or more training techniques described herein. Deep learning may be advanced using any appropriate learning network and the computing capabilities of the datacenter 600. As such, a deep neural network (DNN), a recurrent neural network (RNN) or a convolutional neural network (CNN) may be supported either simultaneously or concurrently using the hardware in the datacenter. Once a network is trained and successfully evaluated to recognize data within a subset or a slice, for instance, the trained network can provide similar representative data for using with the collected data.

In at least one embodiment, datacenter 600 may use CPUs, application-specific integrated circuits (ASICs), GPUs, DPUs, QPUs, PPUs, FPGAs, or other hardware to perform training and/or inferencing using above-described resources. QPUs configured to perform one or more operations associated with a quantum algorithm In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU that the local qubits are associated with. Moreover, one or more software and/or hardware resources described above may be configured as a service to allow users to train or performing inferencing of information, such as pressure, flow rates, temperature, and location information, or other artificial intelligence services.

Inference and/or training logic 615 may be used to perform inferencing and/or training operations associated with one or more embodiments. In at least one embodiment, inference and/or training logic 615 may be used in system FIG. 6A for inferencing or predicting operations based, at least in part, on weight parameters calculated using neural network training operations, neural network functions and/or architectures, or neural network use cases described herein. In at least one embodiment, inference and/or training logic 615 may include, without limitation, hardware logic in which computational resources are dedicated or otherwise exclusively used in conjunction with weight values or other information corresponding to one or more layers of neurons within a neural network. In at least one embodiment, inference and/or training logic 615 may be used in conjunction with an application-specific integrated circuit (ASIC), such as Tensorflow® Processing Unit from Google, an inference processing unit (IPU) from Graphcore™, or a Nervana® (such as “Lake Crest”) processor from Intel Corp.

In at least one embodiment, inference and/or training logic 615 may be used in conjunction with central processing unit (CPU) hardware, graphics processing unit (GPU) hardware or other hardware, such as field programmable gate arrays (FPGAs). In at least one embodiment, inference and/or training logic 615 includes, without limitation, code and/or data storage modules which may be used to store code (such as graph code), weight values and/or other information, including bias values, gradient information, momentum values, and/or other parameter or hyperparameter information. In at least one embodiment, each of the code and/or data storage modules is associated with a dedicated computational resource. In at least one embodiment, the dedicated computational resource includes computational hardware that further include one or more ALUs that perform mathematical functions, such as linear algebraic functions, only on information stored in code and/or data storage modules, and results from which are stored in an activation storage module of the inference and/or training logic 615.

In the following description, numerous specific details are set forth to provide a more thorough understanding of at least one embodiment. However, it will be apparent to one skilled in the art that the inventive concepts may be practiced without one or more of these specific details.

FIG. 6B is a block diagram that schematically illustrates a computing system 650 that may be a data center or a High-Performance Computing (HPC) cluster, in which at least one embodiment from FIGS. 1-5B may be used. The computing system 650 may include a plurality of subsystems, e.g. multiple processing devices coupled to each other, multiple network devices, and multiple networks, according to at least one embodiment. The computing system 650 is designed with multiple integrated circuits (referred to as processing devices), where each integrated circuit can include one or more CPUs and GPUs, forming a powerful and flexible architecture.

The various processing devices are interconnected via an NVLink or other high-speed interconnect, enabling high-speed communication between the subsystems, and are also connected through a NIC or DPU to ensure efficient data transfer across computing system 650 and to one or more external networks 6530, 6536. In the present example, system 650 comprises a packet switch 6548 that connects NIC/DPU 6528 to network 6530, and a packet switch 6550 that connects NIC/DPU 6532 to network 6536.

The coupling of processing devices through NVLink allows for seamless data exchange and parallel processing, enhancing overall computational performance. The processing devices are connected to multiple networks through one or more network interface cards (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 650 can include one or more CPUs and one or more GPUs.

FIG. 6B also demonstrates an example architecture of a multi-GPU architecture. As illustrated in the figure, computing system 650 includes a processing device 6502 with a multi-GPU architecture. In particular, processing device 6502 may be a system-on-chip and includes multiple subsystems such as a CPU 6506, a GPU 6508, and a GPU 6510. CPU 6506 can be coupled to GPU 6508 via a die-to-die (D2D) or chip-to-chip (C2C) interconnect 6512, such as a Ground-Referenced Signaling interconnect (GRS interconnect). CPU 6506 can be coupled to GPU 6510 via a D2D or C2C interconnect 6514. CPU 6506 can also couple to GPU 6508 and GPU 6510 via PCIe interconnects.

CPU 6506 can be coupled to one or more NICs or DPUs, which are coupled to one or more networks. For example, as illustrated in FIG. 6B, CPU 6506 is coupled to a first NIC/DPU 6526, which is coupled to a network 6530. CPU 6506 is also coupled to a second NIC/DPU 6528, which is coupled to network 6530 via switch 6548. NIC/DPU 6526 and NIC/DPU 6528 can be coupled to network 6530 over Ethernet (ETH), NVLINK or InfiniBand (IB) connections, for example.

Computing system 650 also includes a processing device 6504 with a multi-GPU architecture. In particular, processing device 6504 includes multiple subsystems including a CPU 6516, a GPU 6518, and a GPU 6520. CPU 6516 can be coupled to GPU 6518 via an D2D or C2C interconnect 6522. CPU 6516 can be coupled to GPU 6520 via a D2D or C2C interconnect 6524. CPU 6516 can also couple to GPU 6518 and GPU 6520 via PCIe interconnects. CPU 6516 can be coupled to one or more NICs or DPUs, which are coupled to one or more networks. For example, as illustrated in FIG. 6B, CPU 6516 is coupled to a first NIC/DPU 6532, which is coupled to a network 6536. CPU 6516 is also coupled to a second NIC/DPU 6534, which is coupled to network 6536 via switch 6550. NIC/DPU 6532 and NIC/DPU 6534 can be coupled to network 6536 over Ethernet (ETH), NVLINK or InfiniBand (IB) connections.

In at least one embodiment, processing device 6502 and processing device 6504 can communication with each other via a NIC/DPU 6538, such as over PCIe interconnects. Processing device 6502 and processing device 6504 can also communicate with each other over a high-bandwidth communication interconnects 6540, such as an NVLink interconnect or other high-speed interconnects. The packet switches in FIG. 6B may comprise, for example, Nvidia Quantum-2 switches. The NICs/DPUs in the figure may comprise, for example, Nvidia Bluefield DPUs.

In various embodiments, any of the network devices of the computing system 650, e.g., any of NICs/DPUs 6526, 6528, 6532, 6534 and 6538, and/or any of switches 6548 and 6550, may include a shaped leak sensor that can match a geometry around components and features in the computing system 650 and that can be communicatively coupled together to extend leak detection capabilities.

FIG. 6C illustrates an example computing environment 670, in which at least one embodiment from FIGS. 1-5B may be used. The example computing environment 670 may include a shaped leak sensor that can match a geometry around components and features in the example computer environment 670 and that can be communicatively coupled together to extend leak detection capabilities. It should be appreciated that embodiments of the present disclosure may also be used with reference to alternative environments and that specific discussion of components may be provided by way of non-limiting example and may include equivalents. Moreover, various features have been removed for clarity and conciseness. Additionally, systems and methods may be used with a variety of different architectures. The example computing environment 670 may include a server 672 which may be used to perform HPC workloads, such as AI training or machine learning model training. In an embodiment, the server 672 may be an application instance or a compute node. The server 672 may include a CPU 674 associated with a switch 676, such as a peripheral component interconnect express (PCIe) switch, which may control at least some data transmission over communication paths interconnecting various components. In an embodiment, the CPU 674 may include a root complex processor.

The PCIe switch 676 may also be associated with a GPU 678 and a DPU 680, and may transmit data between at least some of the CPU 674, the GPU 678, the DPU 680, and other components. In an embodiment, the PCIe switch 676 may be associated with more than one GPU or more than one DPU. In another embodiment, the PCIe switch 676 may be located within the DPU 680. The PCIe switch 676 may manage the transfer of at least some data between the CPU 674, the GPU 678, and the DPU 680. In another embodiment, the number of GPUs associated with the PCIe switch 676 may be equal to the number of DPUs associated with the PCIe switch 676. In at least one embodiment, the server 672 may include, without limitation, any number of the CPUs 674, the PCIe switches 676, the GPUs 678, and/or the DPUs 680, in any combination. For example, in at least one embodiment, server 672 could include eight, sixteen, thirty-two, and/or more GPUs 678. In at least one embodiment, communication paths interconnecting various components, including but not limited to the CPU 674, the PCIe switch 676, the GPU 678, and the DPU 680, in FIG. 6C may be implemented using any suitable protocols, such as peripheral component interconnect (PCI) based protocols (e.g., PCIe), or other bus or point-to-point communication interfaces and/or protocol(s), such as NV-Link high-speed interconnect, or interconnect protocols.

The DPU 680 may include a network interface card (NIC) 682, a DDR memory 680B, and a non-volatile memory express (NVMe) device 680C. The NIC 682 may be able to interface with a network 684, which may also interface with additional NVMe devices available to the DPU 680, such as over fabric. In an embodiment, the DPU 680 may not include the NVMe device 680C. In another embodiment, the NVMe device 680C may be located on the server 672 and not on the DPU 680. In yet another embodiment, the computing environment 670 may include more than one of the NVMe device 146, such as a first NVMe device in the DPU 140 and a second first NVMe device on the server 672 and associated directly with the PCIe switch 676. In an embodiment, the DPU 680 may not include the DDR memory 680B and may include a computational storage services (CSS) in place of, or in addition to, the DDR memory 680B. For example, computing environment 670 may include DPU computational storage (CS) memory 680D available to the DPU 680 as part of the CSS. The network 684 may be able to interface with the DPU CS memory 680D through the NIC 682, according to any suitable interface protocol, such as remote direct memory access (RDMA) over Ethernet, InfiniBand, Fiber Channel, etc..

The total memory of the computing environment 670 available for data storage may be expanded through the use of the DPU 680 on nodes of the system. The DPU 680 may have access to a pool 680A of memory already available to the server 672, such as double data rate (DDR) memory, on-board NVMe devices, NVMe devices over fabric, and CS. The pool 680A of memory may include at least one of the DDR memory 680B, NVMe 680C, and the DPU CS memory 680D. The DPU 680 may also be able to access the available memory of other DPUs as part of the pool 680A, and other DPUs may be able to access the available memory of DPU 680, such as the pool 680A. This available memory can be accessed and utilized for data storage, without the addition of compute resources, such as compute nodes, which would be required using other solutions. The available pool 680A accessible to the DPU 680 may be provisioned for the server 672 to expand the total memory available for data storage, such as to reduce the data storage load on the CPU 674 or the GPU 678, which can instead increase the utilization of their memory for processing. For example, during training of an AI, the model states, residual states, activation functions, and checkpoints can be stored, or offloaded, on the pool 680A accessible to the DPU 680.

FIG. 6D illustrates a computer system 690, according to at least one example, in which at least one embodiment from FIGS. 1-5B may be used. In at least one embodiment, computer system 690 is configured to implement various processes and methods described throughout this disclosure.

In at least one embodiment, computer system 690 comprises, without limitation, at least one central processing unit (“CPU”) 6902 that is connected to a communication bus 6910 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 690 includes, without limitation, a main memory 6904 and control logic (e.g., implemented as hardware, software, or a combination thereof) and data are stored in main memory 6904 which may take form of random access memory (“RAM”). In at least one embodiment, a network interface subsystem (“network interface”) 6922 provides an interface to other computing devices and networks for receiving data from and transmitting data to other systems from computer system 690.

In at least one embodiment, computer system 690, in at least one embodiment, includes, without limitation, input devices 6908, parallel processing system 6912, and display devices 6906 which can be implemented using a conventional cathode ray tube (“CRT”), liquid crystal display (“LCD”), light emitting diode (“LED”), plasma display, or other suitable display technologies. In at least one embodiment, user input is received from input devices 6908 such as keyboard, mouse, touchpad, microphone, and more. In at least one embodiment, each of foregoing modules can be situated on a single semiconductor platform to form a processing system.

In at least one embodiment, computer programs in form of machine-readable executable code or computer control logic algorithms are stored in main memory 6904 and/or secondary storage. Computer programs, if executed by one or more processors, enable system 690 to perform various functions in accordance with at least one embodiment. memory 6904, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 6902; parallel processing system 6912; an integrated circuit capable of at least a portion of capabilities of both CPU 6902; parallel processing system 6912; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 690 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 6912 includes, without limitation, a plurality of parallel processing units (“PPUs”) 6914 and associated memories 6916. In at least one embodiment, PPUs 6914 are connected to a host processor or other peripheral devices via an interconnect 6918 and a switch 6920 or multiplexer. In at least one embodiment, parallel processing system 6912 distributes computational tasks across PPUs 6914 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 6914, although such shared memory may incur performance penalties relative to use of local memory and registers resident to a PPU 6914. In at least one embodiment, operation of PPUs 6914 is synchronized through use of a command such as_syncthreads(), wherein all threads in a block (e.g., executed across multiple PPUs 6914) to reach a certain point of execution of code before proceeding.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. In at least one embodiment, use of term “set” (e.g., “a set of items”) or “subset” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present. In addition, unless otherwise noted or contradicted by context, term “plurality” indicates a state of being plural (e.g., “a plurality of items” indicates multiple items). In at least one embodiment, number of items in a plurality is at least two, but can be more when so indicated either explicitly or by context. Further, unless stated otherwise or otherwise clear from context, phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors.

In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause computer system to perform operations described herein. In at least one embodiment, set of non-transitory computer-readable storage media comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors—for example, a non-transitory computer-readable storage medium store instructions and a main central processing unit (“CPU”) executes some of instructions while a graphics processing unit (“GPU”) executes other instructions. In at least one embodiment, different components of a computer system have separate processors and different processors execute different subsets of instructions.

In at least one embodiment, an arithmetic logic unit is a set of combinational logic circuitry that takes one or more inputs to produce a result. In at least one embodiment, an arithmetic logic unit is used by a processor to implement mathematical operation such as addition, subtraction, or multiplication. In at least one embodiment, an arithmetic logic unit is used to implement logical operations such as logical AND/OR or XOR. In at least one embodiment, an arithmetic logic unit is stateless, and made from physical switching components such as semiconductor transistors arranged to form logical gates. In at least one embodiment, an arithmetic logic unit may operate internally as a stateful logic circuit with an associated clock. In at least one embodiment, an arithmetic logic unit may be constructed as an asynchronous logic circuit with an internal state not maintained in an associated register set. In at least one embodiment, an arithmetic logic unit is used by a processor to combine operands stored in one or more registers of the processor and produce an output that can be stored by the processor in another register or a memory location.

In at least one embodiment, as a result of processing an instruction retrieved by the processor, the processor presents one or more inputs or operands to an arithmetic logic unit, causing the arithmetic logic unit to produce a result based at least in part on an instruction code provided to inputs of the arithmetic logic unit. In at least one embodiment, the instruction codes provided by the processor to the ALU are based at least in part on the instruction executed by the processor. In at least one embodiment combinational logic in the ALU processes the inputs and produces an output which is placed on a bus within the processor. In at least one embodiment, the processor selects a destination register, memory location, output device, or output storage location on the output bus so that clocking the processor causes the results produced by the ALU to be sent to the desired location.

Accordingly, in at least one embodiment, computer systems are configured to implement one or more services that singly or collectively perform operations of processes described herein and such computer systems are configured with applicable hardware and/or software that allow performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to practice of disclosure.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, “processor” may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. In at least one embodiment, terms “system” and “method” are used herein interchangeably insofar as system may embody one or more methods and methods may be considered a system.

In present document, references may be made to obtaining, acquiring, receiving, or inputting analog or digital data into a subsystem, computer system, or computer-implemented machine. In at least one embodiment, process of obtaining, acquiring, receiving, or inputting analog and digital data can be accomplished in a variety of ways such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing entity to acquiring entity. References may also be made to providing, outputting, transmitting, sending, or presenting analog or digital data. In at least one embodiment, processes of providing, outputting, transmitting, sending, or presenting analog or digital data can be accomplished by transferring data as an input or output parameter of a function call, a parameter of an application programming interface or interprocess communication mechanism.

Although descriptions herein set forth example implementations of described techniques, other architectures may be used to implement described functionality, and are intended to be within scope of this disclosure. Furthermore, although specific distributions of responsibilities may be defined above for purposes of description, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A system for leak detection in a computing environment, comprising:
a shaped leak sensor comprising an insulating material and a plurality of conductive traces, wherein the shaped leak sensor is configured to be shaped to match at least a layout around a component in the computing environment; and
a detector to monitor an input from the shaped leak sensor to determine one or more of a plurality of states associated with the shaped leak sensor.

2. The system of claim 1, wherein the plurality of conductive traces is comprised on a first side of the insulating material, and wherein an adhesive is comprised on a second side of the insulating material.

3. The system of claim 1, wherein the shaped leak sensor is shaped to fit around at least part of a central processing unit (CPU), a graphics processing unit (GPU), or a data processing unit (DPU), and wherein the CPU, GPU or the DPU form the component in the computing environment.

4. The system of claim 1, wherein the insulating material is a flexible insulating material is one or more of polyimide, polyamide, polyester, polyethylene naphthalate, or Polytetrafluoroethylene, and wherein the plurality of conductive traces comprises one or more of gold, graphite, silver, or nickel.

5. The system of claim 1, further comprising:
a foam or volumetric material at a perimeter of the shaped leak sensor to support pooling of fluid from a leak in the computing environment.

6. The system of claim 1, further comprising:
one or more of a prong or a socket to allow for the shaped leak sensor to be associated with a further shaped leak sensor by a plug-in arrangement and to be associated with the detector either directly or through the further shaped leak sensor.

7. The system of claim 1, further comprising:
at least one pair of parallel conductive traces in the plurality of conductive traces, wherein the at least one pair of parallel conductive traces is configured to be shaped to provide the shaped leak sensor and is configured to provide redundancy in sensing a leak upon at least one conductive trace of the at least one pair of parallel conductive traces being shaped.

8. The system of claim 1, wherein the shaped leak sensor is further configured for calibration or testing for one of different applications in the computing environment, wherein at least the calibration is performed in a dry version of the computing environment to determine reference values for the plurality of states, and wherein the detector is a voltage-based leak detection that is configured to distinguish between the plurality of states based in part on different voltages provided in the input with respect to the reference values.

9. The system of claim 8, wherein at least the testing is based in part on at least one electrical component coupled to one or more of the shaped leak sensor to simulate different resistances.

10. A shaped leak sensor comprising an insulating material, a printed or applied thereon plurality of conductive traces on a first side, and an adhesive on a second side, wherein the shaped leak sensor is shaped by one or more cuts to match at least a layout around a component in a computing environment, and wherein the shaped leak sensor is to provide an input to a detector to enable monitoring of a leak and to enable determining of one or more of a plurality of states associated with the shaped leak sensor.

11. The shaped leak sensor of claim 10, wherein the insulating material is a flexible insulating material comprising one or more of polyimide, polyamide, polyester, polyethylene naphthalate, or Polytetrafluoroethylene, and wherein the plurality of conductive traces comprises one or more of gold, graphite, silver, or nickel.

12. The shaped leak sensor of claim 10, further comprising:
a foam or volumetric material at a perimeter of the shaped leak sensor to support pooling of fluid from a leak in the computing.

13. The shaped leak sensor of claim 10, further comprising:
one or more of a prong or a socket to allow for the shaped leak sensor to be associated with a further shaped leak sensor by a plug-in arrangement and to be associated with the detector either directly or through the further shaped leak sensor.

14. The shaped leak sensor of claim 10, further comprising:
at least one pair of parallel conductive traces in the plurality of conductive traces, wherein the at least one pair of parallel conductive traces is configured to be shaped to provide the shaped leak sensor and is configured to provide redundancy in sensing a leak upon at least one conductive trace of the at least one pair of parallel conductive traces being shaped.

15. The shaped leak sensor of claim 10, wherein the shaped leak sensor is further configured for calibration or testing for one of different applications in the computing environment, wherein at least the calibration is performed in a dry version of the computing environment to determine reference values for the plurality of states, and wherein the detector is a voltage-based leak detector and is configured to distinguish between the plurality of states based in part on different voltages provided in the input with respect to the reference values.

16. The shaped leak sensor of claim 15, wherein at least the testing is based in part on at least one electrical component coupled to one or more of the shaped leak sensor to simulate the different resistances.

17. A method for leak detection in a computing environment, comprising:
preparing a shaped leak sensor comprising an insulating material, a printed or applied thereon plurality of conductive traces on a first side, and an adhesive on a second side;
enabling a shape in the shaped leak sensor to match at least a layout around a component in the computing environment; and
monitoring, using a detector, an input from the shaped leak sensor to determine one or more of a plurality of states associated with the shaped leak sensor.

18. The method of claim 17, wherein the insulating material is a flexible insulating material comprising one or more of polyimide, polyamide, polyester, polyethylene naphthalate, or Polytetrafluoroethylene, and wherein the plurality of conductive traces comprises one or more of gold, graphite, silver, or nickel.

19. The method of claim 17, further comprising:
enabling a foam or volumetric material at a perimeter of the shaped leak sensor to support pooling of fluid from a leak in the computing environment.

20. The method of claim 17, further comprising
allowing the shaped leak sensor to be associated with a further shaped leak sensor by a plug-in arrangement using one or more of a prong or a socket; and
associating the detector either directly or through the further shaped leak sensor.

21. The method of claim 17, further comprising:
enabling at least one pair of parallel conductive traces in the plurality of conductive traces; and
configuring the at least one pair of parallel conductive traces to be shaped to provide the shaped leak sensor and to provide redundancy in sensing a leak upon at least one conductive trace of the at least one pair of parallel conductive traces being shaped.

22. The method of claim 17, further comprising:
calibrating or testing the shaped leak sensor for one of different applications in the computing environment, wherein at least the calibration is performed in a dry version of the computing environment to determine reference values for the plurality of states, and wherein the detector is a voltage-based leak detector that is configured to distinguish between the plurality of states based in part on different voltages provided in the input with respect to the reference values.

23. A datacenter comprising:
one or more racks comprising one or more server trays;
one or more components in the one or more racks, the one or more components to perform at least part of a workload in the datacenter;
a shaped leak sensor comprising an insulating material and a plurality of conductive traces, wherein the shaped leak sensor is configured to be shaped to match at least a layout around the one or more component; and
a detector to monitor an input from the shaped leak sensor to determine one or more of a plurality of states associated with the shaped leak sensor.
